(19) United States
(12) Patent Application Publication
(10) Pub. No.: US 2012/0258414 A1
(43) Pub. Date: Oct. 11, 2012

(54) SUBSTRATE SUPPORT INSTRUMENT, AND VERTICAL HEAT TREATMENT APPARATUS AND DRIVING METHOD THEREOF

(75) Inventors: Hiroyuki MATSUURA, Oshu-shi (JP); Katsuya TOBA, Oshu-shi (JP)

(73) Assignee: TOKYO ELECTRON LIMITED, Tokyo (JP)

(21) Appl. No.: 13/441,519

(22) Filed: Apr. 6, 2012

(30) Foreign Application Priority Data
Apr. 8, 2011 (JP) 2011-86618
Aug. 29, 2011 (JP) 2011-186264
Feb. 9, 2012 (JP) 2012-26464

(51) Int. Cl. H01L 21/677; F27D 5/00; F27D 3/00; H01L 21/477

(52) U.S. Cl. 432/5; 432/258; 432/95; 432/239; 432/9

(57) ABSTRACT

A substrate support instrument includes a first support instrument portion and a second support instrument portion detachably combined with each other. Each of the first support instrument portion and second support instrument portion includes: a ceiling plate and a bottom plate facing each other upward and downward; a support pillar disposed in plurality along a peripheral edge portion of each of the ceiling plate and bottom plate, and configured to connect the ceiling plate and the bottom plate; and a support part disposed at a position corresponding to each of the support pillars, and configured to support a bottom of each substrate. In the support part, a height position is set such that a substrate supported in the first support instrument portion and a substrate supported in the second support instrument portion are alternately arranged, when the first support instrument portion is combined with the second support instrument portion.

### CROSS-REFERENCE TO RELATED APPLICATIONS

This application claims the benefit of Japanese Patent Application Nos. 2011-086618, 2011-186264, and 2012-026464, filed on Apr. 8, 2011, Aug. 29, 2011, and Feb. 9, 2012, respectively, in the Japan Patent Office, the disclosures of which are incorporated herein in their entirety by reference.

### TECHNICAL FIELD

The present disclosure relates to a technology, for example, which mounts a substrate on a substrate support instrument that is used for supporting substrates such as semiconductor wafers in multi stages and loading the substrates into a vertical heat treatment furnace.

### BACKGROUND

As a type of semiconductor manufacturing device, there is a vertical heat treatment apparatus that performs heat treatment on a plurality of semiconductor wafers (hereinafter, referred to as “wafer”) in batches.

The heat treatment apparatus disposes a wafer on a wafer boat having a shelf shape, lifts the wafer boat to load the wafer boat into a heat treatment furnace, and performs heat treatment on a plurality of wafers. In the wafer boat, a backside peripheral edge portion of a wafer is disposed in a groove portion that is formed at a support pillar, and thus a plurality of wafers W, for example, a hundred wafers are disposed in multi stages. At this point, in moving a wafer to load the wafer into a groove portion of the wafer boat, a fork supporting the wafer advances into an upper side of the groove portion and then descends to transfer the wafer to the groove portion, and the fork retreats from a lower side of the groove portion.

In the heat treatment apparatus, in order to increase the number of wafers to be processed, it is required to increase the number of wafers mounted on the wafer boat by narrowing the arrangement pitch of the mounted wafers as much as possible. However, in moving and mounting a wafer, the moving and mounting margin of the fork is necessary, and when the margin is small, since a strict precision is required in moving and mounting the wafer, it is difficult to perform a moving and mounting operation. Therefore, it is not appropriate to further narrow the arrangement pitch of a wafer W from a current pitch of about 6.3 mm.

A conventional semiconductor manufacturing device includes a fixing boat having a first substrate mounting part that supports a portion of a bottom periphery of a substrate to be processed; and a movable boat having a second substrate mounting part that supports the other portion of the bottom periphery of the substrate to be processed. In the conventional semiconductor manufacturing device, a fork moves and mounts the substrate to be processed on the first substrate mounting part of the fixing boat, the movable boat is lifted, and the second substrate mounting part supports the other portion of the substrate to be processed.

However, in the conventional semiconductor manufacturing device, since the fork transfers the substrate to be processed to the first substrate mounting part, it is not possible to narrow an arrangement pitch in order to secure a moving and mounting margin.

### SUMMARY

The present disclosure in some embodiments discloses securing a moving and mounting margin and simultaneously narrowing the arrangement pitch of substrates, in a substrate support instrument where a plurality of substrates are arranged in multi stages.

According to one embodiment of the present disclosure, a substrate support instrument, which supports a plurality of substrates in a shelf shape and loads the substrates into a vertical heat treatment furnace for performing heat treatment, includes: a first support instrument portion and a second support instrument portion detachably combined with each other, each of the first support instrument portion and second support instrument portion including: a ceiling plate and a bottom plate facing each other upward and downward; a support pillar disposed in plurality along a peripheral edge portion of each of the ceiling plate and bottom plate, and configured to connect the ceiling plate and the bottom plate; and a support part disposed at a position corresponding to each of the support pillars, and configured to support a bottom of each of the substrates, wherein in the support part of each of the first support instrument portion and the second support instrument portion, a height position is set such that a substrate supported in the first support instrument portion and a substrate supported in the second support instrument portion are alternately arranged, when the first support instrument portion is combined with the second support instrument portion.

According to another embodiment of the present disclosure, provided is a vertical heat treatment apparatus, which supports a plurality of substrates on a substrate support instrument in a shelf shape and loads the substrates into a vertical heat treatment furnace, including: a first disposing part installed for disposing a first support instrument portion at a position where a substrate is transferred to the first support instrument portion, and using the substrate support instrument of the present disclosure as the substrate support instrument; a second disposing part installed for disposing a second support instrument portion at a position where a substrate is transferred to the second support instrument portion; a combined instrument configured to combine the first support instrument portion disposed at the first disposing part and the second support instrument portion disposed at the second disposing part; and a support instrument ascending/descending apparatus configured to load or unload the substrate support instrument into or from the vertical heat treatment apparatus, the substrate support instrument being configured by the combining instrument for combining the first support instrument portion and the second support instrument portion.

According to another embodiment of the present disclosure, provided is a method of driving a vertical heat treatment apparatus, which supports a plurality of substrates on a substrate support instrument in a shelf shape and loads the substrates into a vertical heat treatment furnace to perform heat treatment on the substrates, including: supporting a substrate in a shelf shape on a first support instrument portion which is disposed at a first disposing part, by using the substrate support instrument of the present disclosure as the substrate support instrument; supporting a substrate in a shelf shape on a second support instrument portion which is disposed at a second disposing part; combining the first support instrument portion and the second support instrument portion to configure a substrate support instrument; and loading the substrate support instrument into the vertical heat treatment furnace to perform heat treatment on a substrate.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIGS. 1A and 1B are a side view schematically illustrating an embodiment of a wafer boat according to the present disclosure, respectively.

FIG. 2 is a perspective view illustrating the wafer boat.

FIG. 3 is a perspective view illustrating a first boat part and a second boat part which constitute the wafer boat.

FIG. 4 is a plan view illustrating a ceiling plate of the wafer boat.

FIG. 5 is a plan view illustrating a support part of the wafer boat.

FIG. 6 is a side view illustrating the first boat part and the second boat part.

FIG. 7 is a perspective view illustrating a portion of the wafer boat.

FIG. 8 is a perspective view illustrating the first boat part and the second boat part.

FIG. 9 is a side view illustrating the first boat part and the second boat part.

FIG. 10 is a plan view illustrating an example of a heat treatment apparatus which includes the wafer boat.

FIG. 11 is a side view illustrating the heat treatment apparatus.

FIG. 12 is a configuration view illustrating an example of a boat combining instrument which is disposed at the heat treatment apparatus.

FIG. 13 is a plan view illustrating an example of the heat treatment apparatus which includes the wafer boat.

FIG. 14 is a configuration view illustrating an example of a coupling instrument which is disposed at the heat treatment apparatus.

FIG. 15 is a side view illustrating the coupling instrument.

FIG. 16 is a plan view illustrating the coupling instrument.

FIG. 17 is a plan view illustrating an example of a boat conveyance instrument which is disposed at the heat treatment apparatus.

FIG. 18 is a side view illustrating the boat conveyance instrument.

FIG. 19 is a side view illustrating an example of an insulation unit which is disposed at the heat treatment apparatus.

FIG. 20 is a side view illustrating another example of a wafer boat according to the present disclosure.

FIG. 21 is a side view illustrating another example of a wafer boat according to the present disclosure.

FIG. 22 is a side view illustrating a substrate moving mounting instrument and a second boat part which are disposed at a heat treatment apparatus including the wafer boat of the other example.

FIG. 23 is a side view illustrating a substrate moving mounting instrument and a second boat part which are disposed at a heat treatment apparatus including the wafer boat of the other example.

FIGS. 24A and 24B are a plan view illustrating a wafer boat of yet another example of the present disclosure, respectively.

FIG. 25 is a side view illustrating a wafer boat of another example of the present disclosure.

FIG. 26 is a side view illustrating a wafer boat of another example of the present disclosure.

FIGS. 27A and 27B are a plan view illustrating a wafer boat of still another example of the present disclosure, respectively.

FIG. 28 is a plan view illustrating another example of a support part according to the present disclosure.

FIG. 29 is a plan view illustrating another example of a support part according to the present disclosure.

FIG. 30 is a side view illustrating another example of a support part according to the present disclosure.

### DETAILED DESCRIPTION

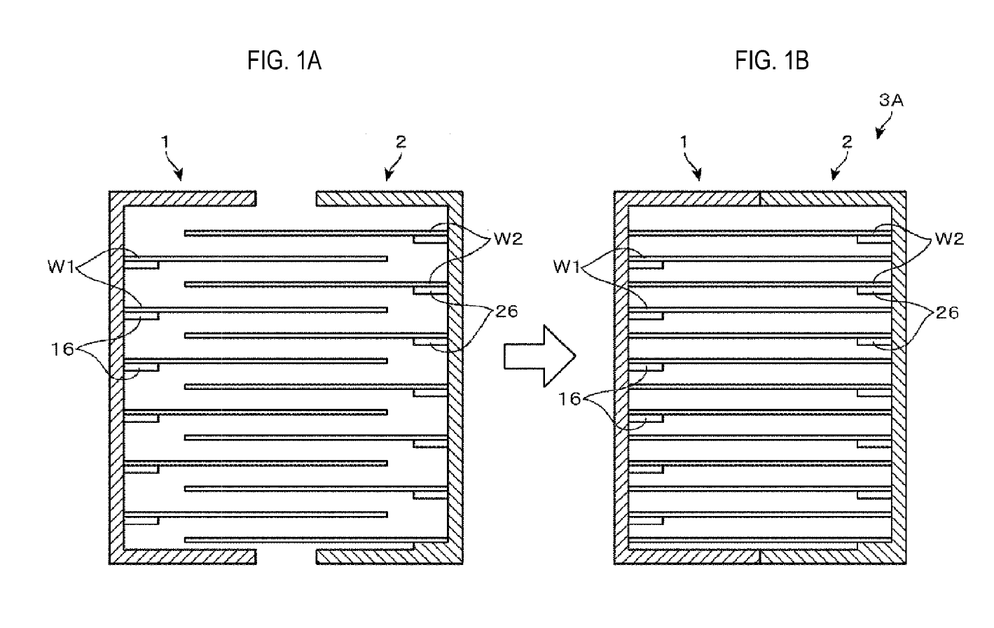

Hereinafter, an embodiment of a vertical heat treatment apparatus according to the present disclosure will be described in detail. First, the summary of a substrate support instrument of the present disclosure that is disposed at the vertical heat treatment apparatus will be described with reference to the schematic view of FIGS. 1A and 1B. The substrate support instrument supports a plurality of wafers W (being a plurality of substrates) in a shelf shape, and loads the wafers W into a vertical heat treatment furnace to heat treat the wafers W. The substrate support instrument includes a first boat part 1 constituting a first support instrument part that is detachably combined with a second support instrument part, and a second boat part 2 constituting the second support instrument part. The first boat part 1 includes a first support part 16 configured to arrange and support a plurality of first wafers W1 at certain intervals in an upward and downward direction, and the second boat part 2 includes a second support part 26 configured to arrange and support a plurality of second wafers W2 at certain intervals in an upward and downward direction.

The first support part 16 and the second support part 26 are configured such that the second support part 26 corresponds to a height position between adjacent first support parts 16 in an upward and downward direction. Furthermore, the first wafer W1 and the second wafer W2 are respectively mounted on the first boat part 1 and the second boat part 2, and then combined with one wafer boat 3. Therefore, the first wafer W1 and the second wafer W2 are alternately mounted on the wafer boat 3.

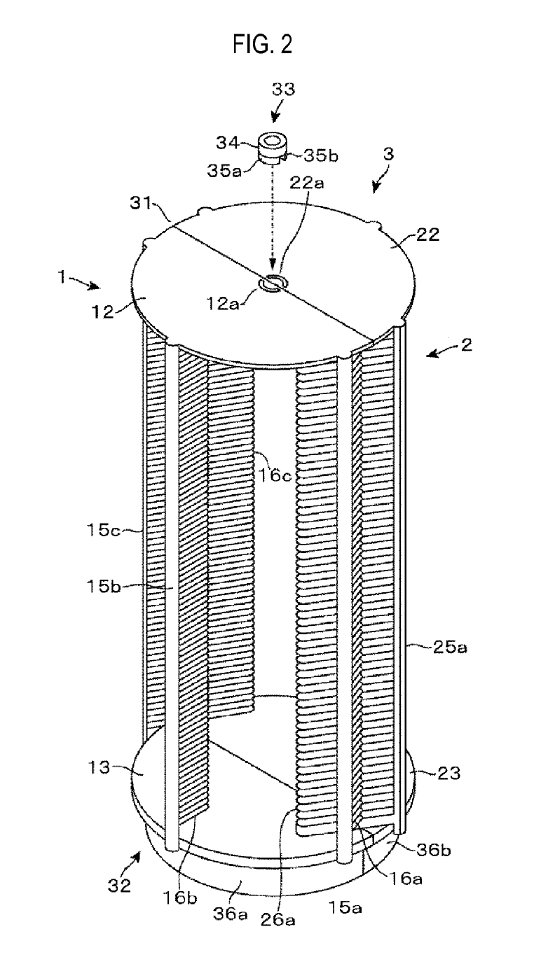

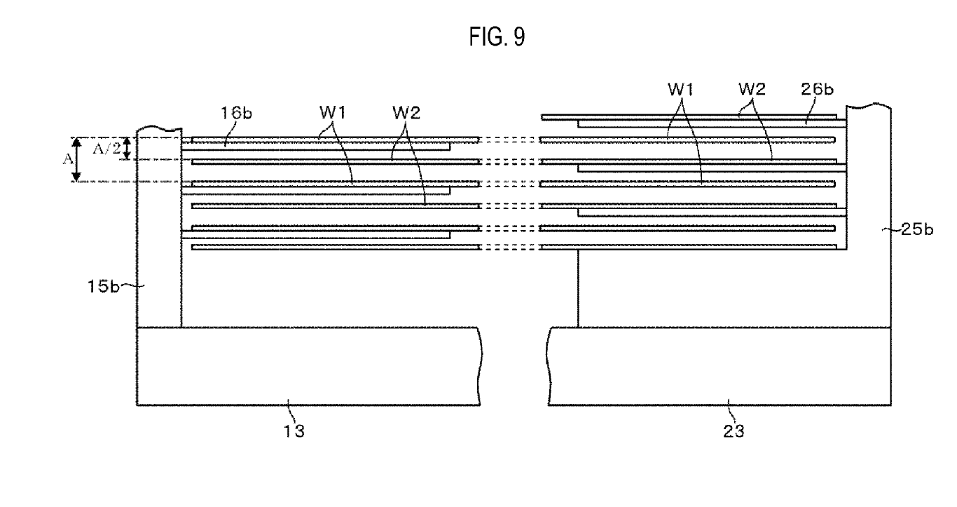

The details of the wafer boat 3 will be described below with reference to FIGS. 2 to 9. The first boat part 1 includes a semicircular ceiling plate 12 and a semicircular bottom plate 13, and the second boat part 2 includes a semicircular ceiling plate 22 and a semicircular bottom plate 23. The ceiling plates 12 and 22 and the bottom plates 13 and 23 are disposed to face each other upward and downward. As illustrated in FIGS. 2 to 4, for example, the ceiling plate 12 is configured with a semicircle of one side that is cut from a central line passing through the center of a circle, and the ceiling plate 22 is configured with a semicircle of the other side that is cut from the central line. The bottom plates 13 and 23, for example, are formed in the same shape as that of the ceiling plates 12 and 22. Therefore, the respective ceiling plates 12 and 22 and the respective bottom plates 13 and 23 of the first and second boat parts 1 and 2 are configured such that a linear region 14 configured with the central line joins a linear region 24 configured with the central line. When the ceiling plate 12 joins the ceiling plate 22, a circular ceiling plate 31 of the wafer boat 3 is formed, and when the bottom plate 13 joins the bottom plate 23, a circular bottom plate 32 of the wafer boat 3 is formed.

Moreover, the first boat part 1 is disposed in plurality along a peripheral edge portion of the ceiling plate 12 and a peripheral edge portion of the bottom plate 13 and, for example, includes three support pillars 15a to 15c that connect a corresponding ceiling plate 12 and a corresponding bottom plate 13. For example, as illustrated in FIGS. 2 to 5, the three support pillars 15a to 15c are disposed to be separated from each other along the peripheral edge portion of the ceiling plate 12 and the peripheral edge portion of the bottom plate 13. The support pillar 15b of the center is disposed at an approximate center portion of an outer border of the ceiling plate 12 and bottom plate 13, and the respective support pillars 15a and 15c of both sides are disposed near the linear region 14 of the ceiling plate 12 and bottom plate 13.

In the respective support pillars 15a to 15c, a plurality of support parts 16a to 16c for supporting a bottom of each wafer W1 are disposed at respective positions corresponding to the support pillars 15a to 15c. In the present example, the support parts 16a to 16c are formed as arm portions (which respectively extend from the support pillars 15a to 15c) for support. In order to approximately horizontally support the wafer W1, in the present example, the side support part 16a and the side support part 16c are respectively disposed to approximately horizontally protrude to the outside across the linear region 14 from the ceiling plate 12 and the bottom plate 13, in the respective support pillars 15a and 15c of both sides. Also, for example, the central support part 16b is disposed to be approximately horizontally extended toward the center of the linear region 14, in the central support pillar 15b.

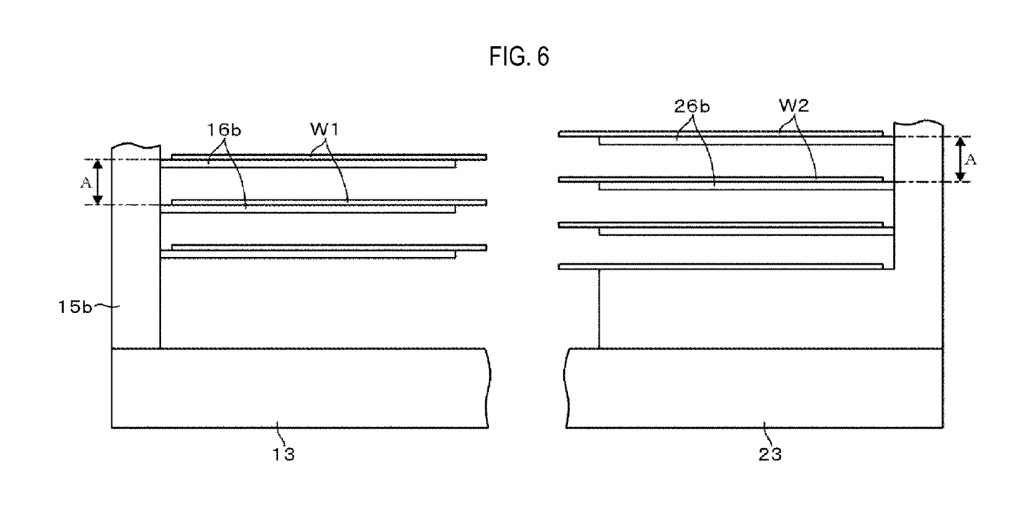

The central support part 16b, the side support part 16a, and the side support part 16c are formed in a plate shape having a narrow width, and fixed at arrangement intervals “A” in the respective support pillar 15b, support pillar 15a, and support pillar 15c. In the present example, a first support part is configured with the central support part 16b, the side support part 16a, and the side support part 16c. Herein, as illustrated in FIG. 6, the arrangement interval denotes an interval between respective upper surfaces of the support parts 16a to 16c and respective lower surfaces of the support parts 16a to 16c.

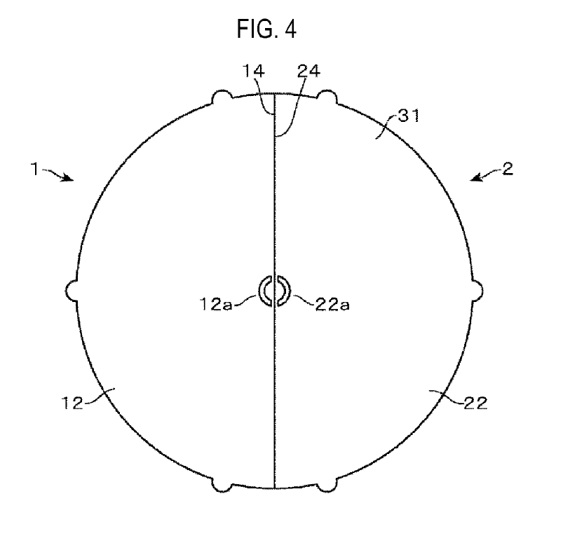

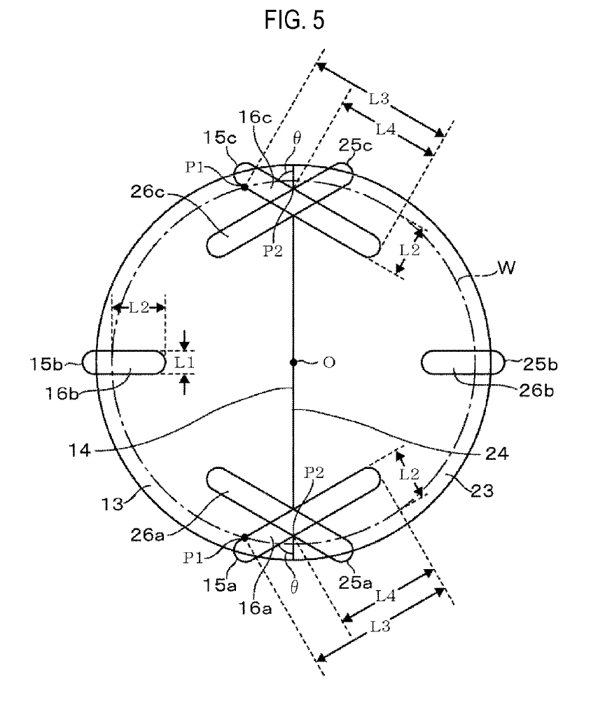

Likewise, the second boat part 2 is disposed in plurality along a peripheral edge portion of each of the ceiling plate 22 and bottom plate 23 and, for example, includes three support pillars 25a to 25c that connect a corresponding ceiling plate 22 and a corresponding bottom plate 23. Also, in the respective support pillars 25a to 25c, a plurality of support parts 26a to 26c for supporting a bottom of each wafer W2 are disposed at respective positions corresponding to the support pillars 25a to 25c. The support parts 26a to 26c are formed as arm portions (which respectively extend from the support pillars 25a to 25c) for support. The respective layouts and shapes of the support pillars 25a to 25c, central support part 26b, side support part 26a, and side support part 26c, as illustrated in FIGS. 4 and 5, are formed to be linearly symmetrical to each other on the basis of linear regions 14 and 24 when the circular ceiling plate 31 of the wafer boat 3 is formed by joining the ceiling plate 12 with the ceiling plate 22 and the circular bottom plate 32 of the wafer boat 3 is formed by joining the bottom plate 13 with the bottom plate 23. The central support part 26b, the side support part 26a, and the side support part 26c are fixed at arrangement intervals of “A” identically to the number of members of the first support part 16a to 16c, in the respective support pillar 25b, support pillar 25a, and support pillar 25c. A second support part is configured with the central support part 26b, the side support part 26a, and the side support part 26c. In order to approximately horizontally support the wafer W2, in the present example, the side support part 26a and the side support part 26c are disposed to extend respectively from the ceiling plate 22 and the bottom plate 23, in the respective support pillars 25a and 25c of both sides.

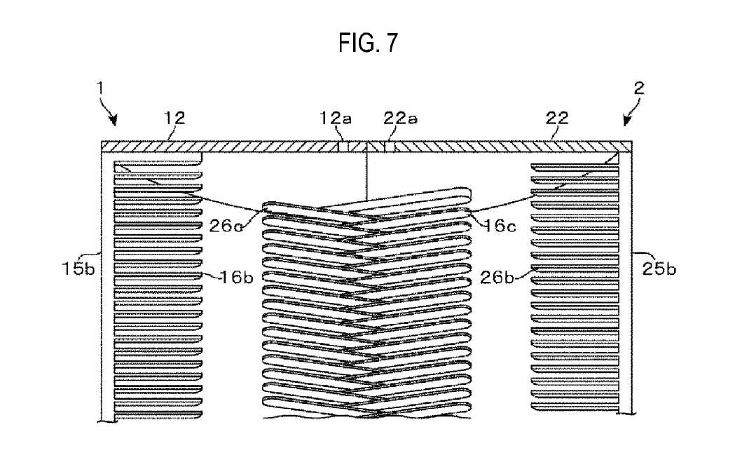

The first boat part 1 and the second boat part 2 are configured in a combinable manner such that the linear region 14 of the ceiling plate 12 and the bottom plate 13 is joined to the linear region 24 of the ceiling plates 22 and the bottom plate 23. In each of the first support part 16a to 16c and the second support part 26a to 26c, a height position is set such that the wafer W1 supported by the first boat part 1 and the wafer W2 supported by the second boat part 2 are alternately arranged when the first boat part 1 and the second boat part 2 are combined with each other. In more detail, for example, an uppermost end surface of the second support part 26a to 26c is lowered by A/2 from an uppermost end surface of the first support part 16a to 16c. Therefore, when the first boat part 1 and the second boat part 2 are combined with each other, as illustrated in FIGS. 7 to 9, the second support part 26a to 26c is moved into a height position between adjacent elements of the first support part 16a to 16c in an upward and downward direction, and the first support part 16a to 16c and the second support part 26a to 26c are arranged upward and downward at arrangement intervals of A/2.

As illustrated in FIG. 5, the first support part 16a to 16c and the second support part 26a to 26c are formed in an arm shape where a support surface supporting a wafer W is extended thinly and lengthily. The support surface of the wafer W is a region on which a back side of the wafer W is mounted, in the first support part 16a to 16c and the second support part 26a to 26c. When the wafer W is transferred to the first support part 16a to 16c and the second support part 26a to 26c, the wafer W may be sometimes moved slightly, and thus, the support surface is a region that has been set in consideration of the moving of the wafer W.

In the first support part 16a to 16c and the second support part 26a to 26c, by enlarging the support surface, stress due to the weight of the wafer W can be dispersed, and thus, the wafer W can be supported stably. However, in the in-surface of the wafer W, a temperature difference can occur between a portion contacting the support surface and a portion that does not contact the support surface. Therefore, it is required to enlarge the support surface by the degree where the in-surface uniformity of heat treatment is not damaged. In the above-described embodiment, the support surface is formed in an arm shape having a narrow width and a long length. For example, the width L1 of each of the first support part 16a to 16c and the second support part 26a to 26c may be set to about 10 mm to about 30 mm, and preferably in some embodiments set to about 20 mm.

Considering the in-surface uniformity of heat treatment in a pattern forming region, it is required in some embodiments to suppress a degree of expansion toward the inside of the pattern forming region. To this end, for example, the length L2 of each of the central support part 16b and the central support part 26b may be set to about 20 mm to about 40 mm, and preferably in some embodiments set to about 30 mm.

Moreover, it is further preferable in some embodiments to dispose the side support part 16a and the side support part 16c to be extended across the linear region 14 and dispose the side support part 26a and the side support part 26c to be extended across the linear region 24, but in consideration of the influence on the pattern forming region, the side support parts 16a, 16c, 26a and 26c may be disposed to be extended near the perimeter of the wafer W. Also, in the present example, in order to increase the in-surface uniformity of heat treatment, a distance from an outer border of the wafer W in a front end portion of the support surface is aligned with the central support part 16b and the central support part 26b. That is, a front end portion of each of the side support parts 16a, 16c, 26a and 26c is disposed to be extended by a distance L2 from the outer border of the wafer W to the internal position of the wafer W. Therefore, a front end portion of each of the central support parts 16b and 26b and a front end portion of each of the side support parts 16a, 16c, 26a and 26c are disposed at the distance L2 from the outer border of the wafer W to the internal position of the wafer W.

To provide a description on an example of the dimension of each of side support parts 16a, 16c, 26a and 26c, the length of the support surface, for example, a distance L3 between an end portion P1 (which is the farthest away from the linear region 14 and the linear region 24) and a front end portion may be set to about 40 mm to about 80 mm as an example, and preferably in some embodiments set to about 60 mm. Also, the length L4 (distance between a front end portion and a portion P2 on the linear region 14 and 24 which is the farthest away from the center O) of a portion that protrudes from each of the linear regions 14 and 24 to an outer side may be set to about 20 mm to about 60 mm, and preferably in some embodiments set to about 40 mm. Moreover, for example, an angle θ between the linear region 14 and the linear region 24 may be set to about 50 degrees to about 70 degrees as an example, and in some instances set to about 60 degrees.

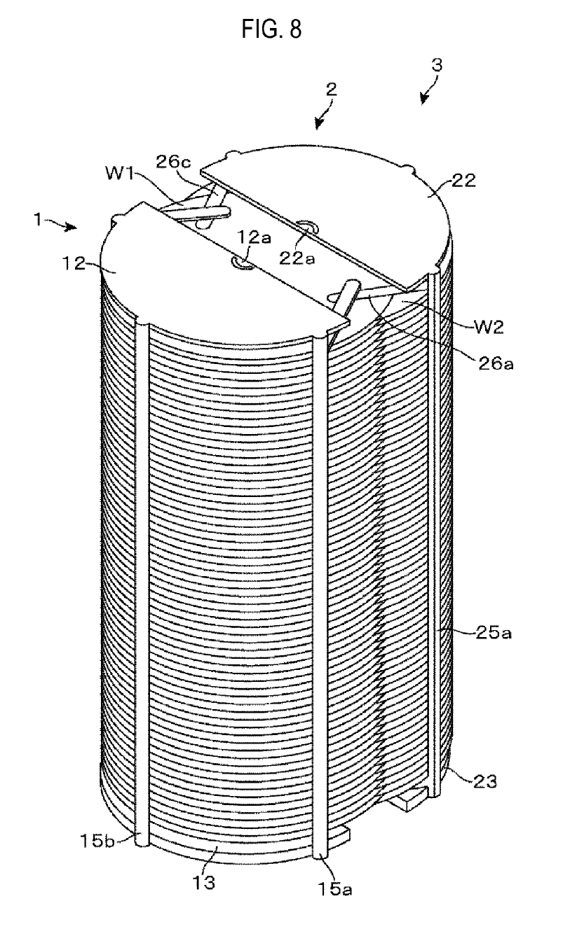

The wafer boat 3, as illustrated in FIG. 8, is configured such that the wafer W1 and the wafer W2 are respectively mounted on the first boat part 1 and the second boat part 2, and then both boat parts 1 and 2 are combined with each other. Furthermore, the wafer boat 3 is configured such that the ceiling plate 12 and the ceiling plate 22 are coupled to each other by a coupling member 33. The coupling member 33 is disposed to be detachable from the first boat part 1 and the second boat part 2 so as to combine the first boat part 1 and the second boat part 2. For example, as illustrated in FIG. 2, the wafer boat 3 includes two foot parts 35a and 35b disposed under a cap part 34. A hole portion 12a is formed at a position corresponding to the foot part 35a, in the ceiling plate 12, and a hole portion 22a is formed at a position corresponding to the foot part 35b, in the ceiling plate 22. Therefore, the first boat part 1 and the second boat part 2 are combined with each other, and then by inserting the foot part 35a of the coupling member 33 into the hole portion 12a of the ceiling plate 12 and inserting the foot part 35b of the coupling member 33 into the hole portion 22a of the ceiling plate 22, the ceiling plate 12 and the ceiling plate 22 are coupled to each other.

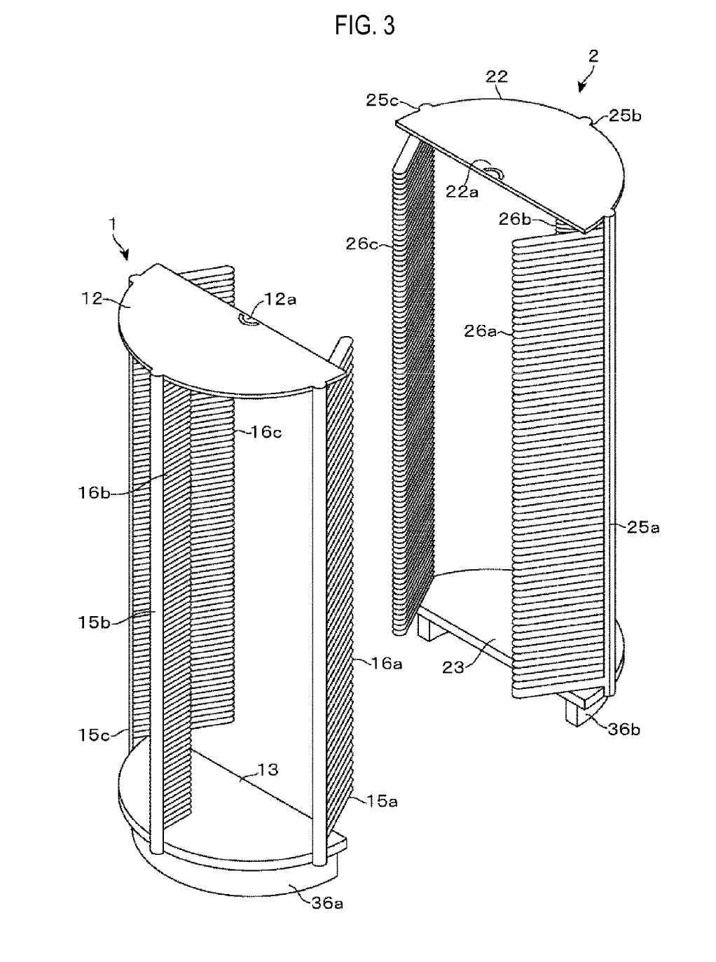

Moreover, as illustrated in FIGS. 2 and 3, a support leg 36a is disposed at a bottom of the bottom plate 13, and a support leg 36b is disposed at a bottom of the bottom plate 23. The support leg 36a is formed in a shape that is capable of supporting the first boat part 1 with the wafer W1 mounted thereon, and the support leg 36b is formed in a shape that is capable of supporting the second boat part 2 with the wafer W2 mounted thereon. Also, in FIGS. 1, 6, 8 and 9, for convenience, the support leg 36a and the support leg 36b are not illustrated. Members (for example, the ceiling plate 12, the bottom plate 13, the support pillars 15a to 15c, the support parts 16a to 16c, the coupling member 33, and the support leg 36a) constituting the first boat part 1 may be formed of quartz as an example, and members (for example, the ceiling plate 22, the bottom plate 23, the support pillars 25a to 25c, the support parts 26a to 26c, the coupling member 33, and the support leg 36b) constituting the second boat part 2 may be formed of quartz as an example.

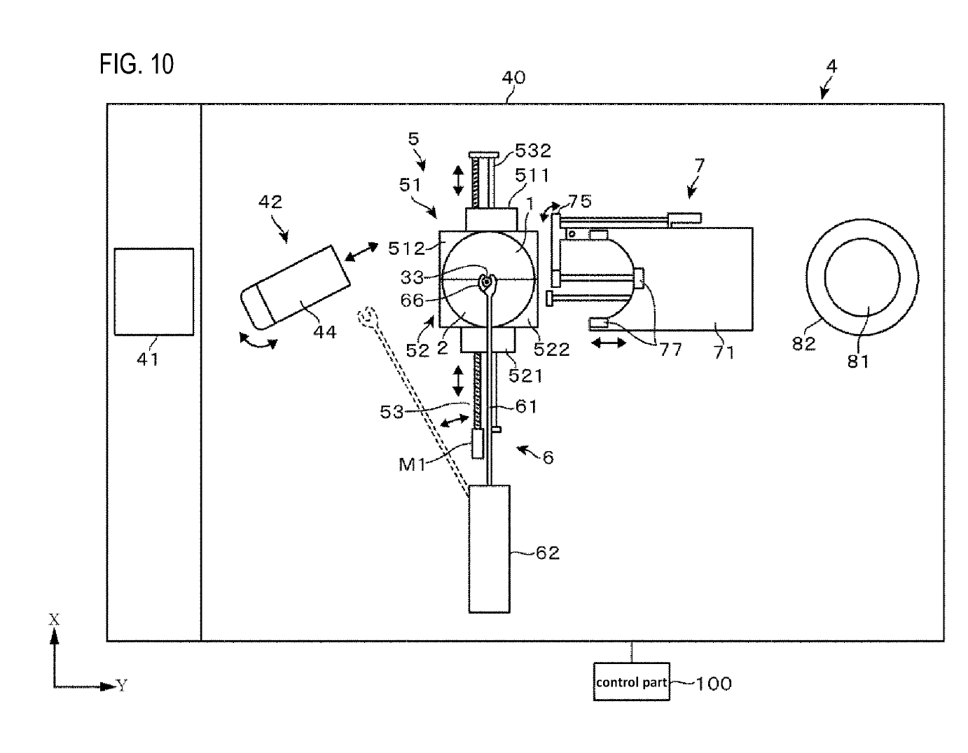

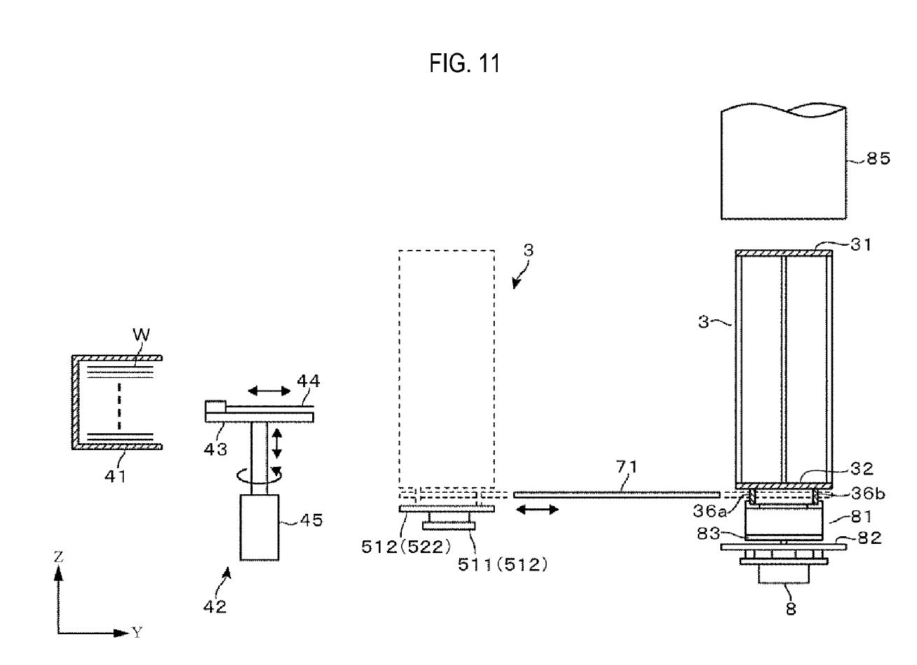

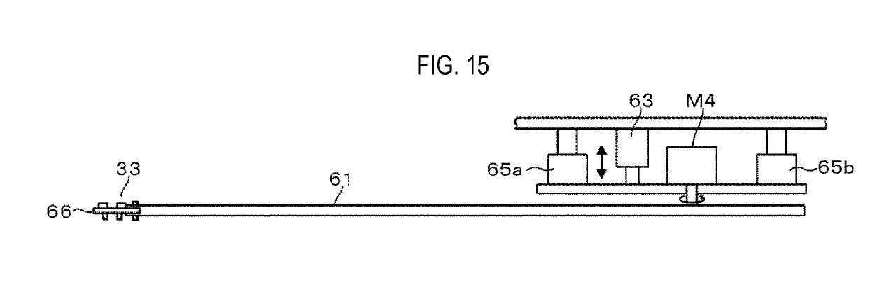

An example of a vertical heat treatment apparatus 4 including the wafer boat 3 will now be described in detail with reference to FIGS. 10 to 19. In FIG. 10, reference numeral 40 indicates a processing chamber, and reference numeral 41 indicates an FOUP where a plurality of wafers W are placed in multi stages. A substrate moving mounting instrument 42 and a boat combining instrument 5 are sequentially disposed at a rear end side of the FOUP 41. The substrate moving mounting instrument 42 performs the moving and mounting of the wafer W between the FOUP 41 and the first boat part 1 and second boat part 2 that are disposed at the boat combining instrument 5. Therefore, as illustrated in FIG. 11, the substrate moving mounting instrument 42 includes a fork 44 that is capable of advancing and retreating along a base crosspiece 43, which is able to move up and down and rotate about a perpendicular axis by a driving instrument 45.

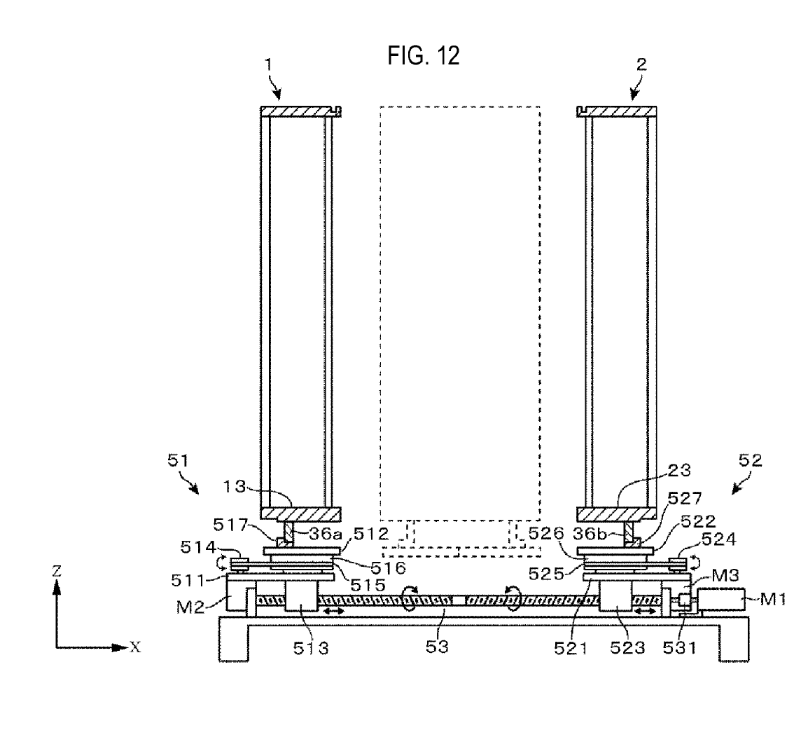

The boat combining instrument 5 is an instrument that combines the first boat part 1 and the second boat part 2 to configure the wafer boat 3. FIG. 12 is a configuration view of the boat combining instrument 5 as seen from the FOUP 41 side. The following description will be made on the assumption of that the left and right direction of the processing chamber 40 is the X direction of FIG. 10 and the length direction of the processing chamber 40 is the Y direction of FIG. 10, when the processing chamber 40 is seen from the FOUP 41 side.

The boat combining instrument 5, as illustrated in FIG. 12, is configured such that a first stage 51 for disposing the first boat part 1 and a second stage for disposing the second boat part 2 are arranged in the left and right direction. The first stage 51 constitutes a first disposing part, and the second stage 52 constitutes a second disposing part. In the present example, when seen from the FOUP 41, the first stage 51 is disposed at the left, and the second stage 52 is disposed at the right.

The first stage 51 includes a first moving base 511 that horizontally moves in a left and right direction, and a first rotation base 512 that is disposed on the moving base 511 and is rotated about the perpendicular axis. A nut part 513 of a ball screw instrument is disposed at a bottom of the first moving base 511, and the first moving base 511 is disposed to be movable in the left and right direction by a motor M1 rotating a ball screw 53 that extends in the left and right direction of the processing chamber 40. Reference numeral 531 indicates a coupling, and reference numeral 532 indicates a guide member (see FIG. 10). Also, the first rotation base 512 is configured in order for a rotation axis 516 to be rotated by the combination of a pulley 514 and a belt 515 that are rotated by a motor M2.

Similar to the first stage 51, the second stage 52 also includes a second moving base 521 that horizontally moves in a left and right direction, and a second rotation base 522 that is disposed on the moving base 521 and is rotated about the perpendicular axis. A nut part 523 of a ball screw instrument is disposed at a bottom of the second moving base 521, and the second moving base 521 is disposed to be movable in the left and right direction by the motor M1 rotating the ball screw 53. Also, the second rotation base 522 is configured in order for a rotation axis 526 to be rotated by the combination of a pulley 524 and a belt 525 that are rotated by a motor M3.

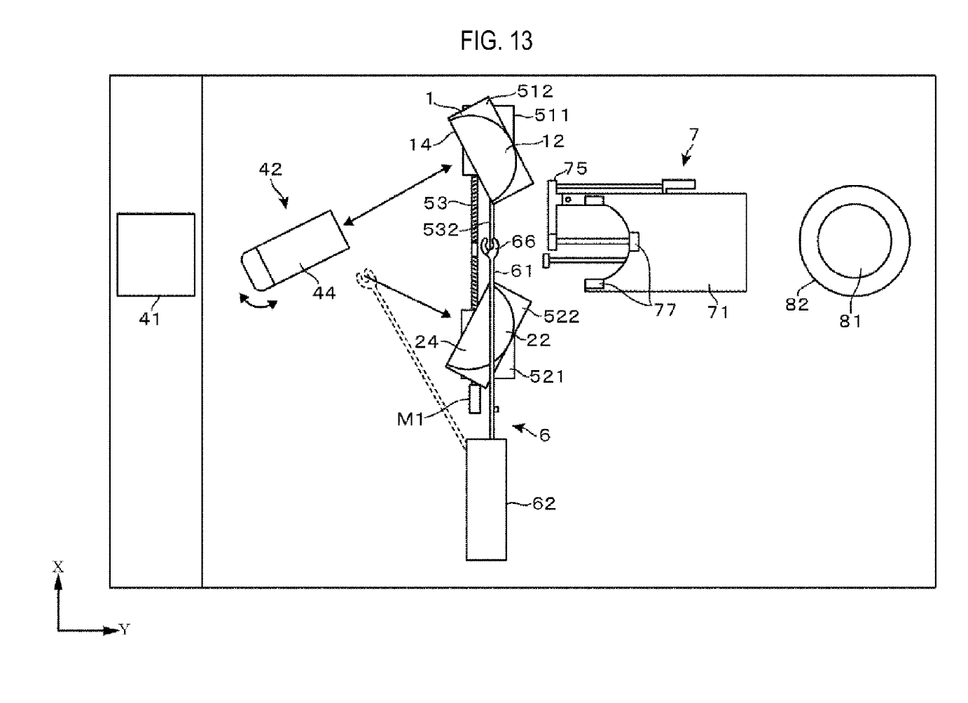

In the ball screw 53, a left screw is formed at a nut side of the first stage 51, and a right screw is formed at a nut side of the second stage 52. Therefore, when rotating the motor M1, the moving base of the first stage 51 is configured to be movable between a moving mounting position (position illustrated in FIGS. 12 and 13) of one end side of the processing chamber 40 and a central combining position (position illustrated in FIG. 10) thereof. The moving base of the second stage 52 is configured to be movable by the rotation of the motor M1, between a moving mounting position of the other end side of the processing chamber 40 and a central combining position thereof. The moving mounting position is a position where the substrate moving mounting instrument 42 transfers the wafer W between the first boat part 1 and the second boat part 2, and the combining position is a position where the first boat part 1 and the second boat part 2 are combined with each other.

Moreover, the first rotation base 512 and the second rotation base 522 is configured to switch a direction between a moving mounting direction (direction illustrated in FIG. 13) and a combining direction (direction illustrated in FIG. 10) by the driving of the motors M2 and M3. The moving mounting direction is a direction where the linear region 14 of each of the ceiling plate 12 and bottom plate 13 of the first boat part 1 faces the substrate moving mounting instrument 42 side, and the linear region 24 of each of the ceiling plate 22 and bottom plate 23 of the second boat part 2 faces the substrate moving mounting instrument 42 side. Also, the combining direction is a direction where the linear region 14 of the first boat part 1 faces the linear region 24 of the second boat part 2.

Herein, a state where the first moving base 511 is in a moving mounting position and the first rotation base 512 located toward a moving mounting direction is in a state where the first stage 51 is in the moving mounting position, and a state where the second moving base 521 is in a moving mounting position and the second rotation base 522 located toward the moving mounting direction is in a state where the second stage 52 is in the moving mounting position. In this case, the substrate moving mounting instrument 42, a boat combining instrument 5, or the first and second boat parts 1 and 2 is/are configured such that the fork 44 of the substrate moving mounting instrument 42 accesses the first support part 16a to 16c of the first boat part 1 when the first stage 51 is in the moving mounting position, and the fork 44 of the substrate moving mounting instrument 42 accesses the second support part 26a to 26c of the second boat part 2 when the second stage 52 is in the moving mounting position.

Moreover, the first rotation base 512 and the second rotation base 522 are located toward the combining direction, and then, by moving the first moving base 511 and the second moving base 521 to the combining position, the linear region 14 of each of the ceiling plate 12 and bottom plate 13 of the first boat part 1 is coupled to the linear region 24 of each of the ceiling plate 22 and bottom plate 23 of the first boat part 2, by which the first boat part 1 and the second boat part 2 are combined with each other, thereby constituting the wafer boat 3. At this point, the first moving base 511 and the second moving base 521 are moved to the combining position, and then, by orienting the first rotation base 512 and the second rotation base 522 toward the combining direction, the first boat part 1 and the second boat part 2 may be combined with each other. Hereinafter, it is assumed that the first stage 51 and the second stage 52 are in the combining position when the first rotation base 512 and the second rotation base 522 are located toward the combining direction and the first moving base 511 and the second moving base 521 are in the combining position.

Moreover, a disposing part 517 where the support leg 36a (being a lower end portion of the first boat part 1) is disposed is installed at a top of the first rotation base 512 of the first stage 51, and a disposing part 527 where the support leg 36b (being a lower end portion of the second boat part 2) is disposed is installed at a top of the second rotation base 522 of the second stage 52. By the weight of the first boat part 1, the first boat part 1 disposes the support leg 36a at the disposing part 517 in a stable state, and thus, the deviation of the position of the first boat part 1 is suppressed when the first stage 51 is moved. By the weight of the second boat part 2, the second boat part 2 disposes the support leg 36b at the disposing part 527 in a stable state, and thus, the deviation of the position of the second boat part 2 is suppressed when the second stage 52 is moved.

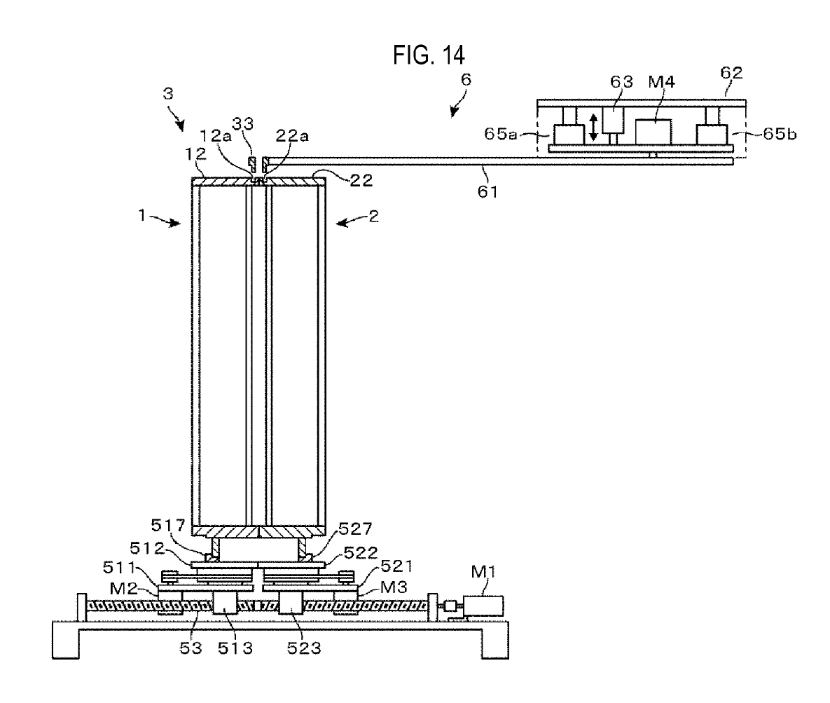

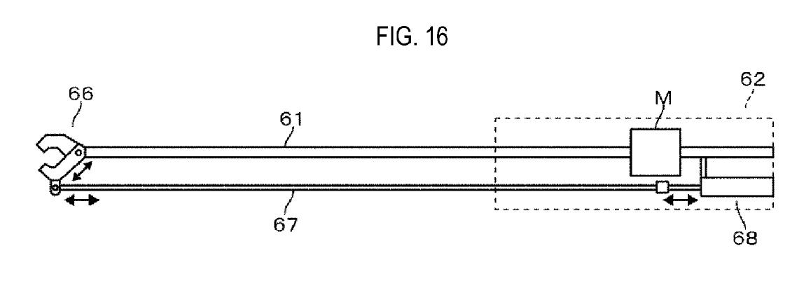

A coupling instrument 6, as illustrated in FIGS. 10 and 14, is installed at an upper side of the boat combining instrument 5. In the present example, the coupling instrument 6 includes an arm member 61, and a base end side of the arm member 61 is connected to a driving instrument 62. The driving instrument 62, as illustrated in FIGS. 14 to 16, includes an ascending/descending instrument 63 that is configured with a cylinder for lifting or dropping the arm 61, and a motor M4 that pivotally moves the arm 61 between a coupling position and a standby position outside the coupling position. In FIGS. 14 and 16, reference numeral 65a is a guide member, and reference numeral 65b is a guide member. The coupling position is a position where a front end of the arm member 61 is in an upper side of the center portion of the ceiling plate 31 of the wafer boat 3 that has been combined in the combining position.

Moreover, a support instrument 66 for supporting the coupling member 33 is disposed at a front end of the arm member 61. The support instrument 66 is connected to a cylinder 68 through a load member 67, and configured to be opened or closed by the cylinder 68 and the load member 67. That is, when the cylinder 68 presses the load member 67, the support instrument 66 is closed and thereby supports the cap part 34 of the coupling member 33, and when the pressure on the load member 67 is removed, the support instrument 66 is opened and thereby disconnects the coupling member 33 therefrom.

Moreover, in the processing chamber 40, a boat conveyance instrument 7 and a boat elevator 8 are sequentially disposed at a rear end side of the boat combining instrument 5. The boat conveyance instrument 7 constitutes a support instrument moving mounting apparatus for moving and mounting the wafer boat 3, in which the first boat part 1 is combined with the second boat part 2, onto the boat elevator 8. In the present example, the boat conveyance instrument 7 is configured to convey the wafer boat 3 between the first and second stages 51 and 52 (which are in the combining position of the boat combining instrument 5) and an insulation unit 81 that is on the boat elevator 8.

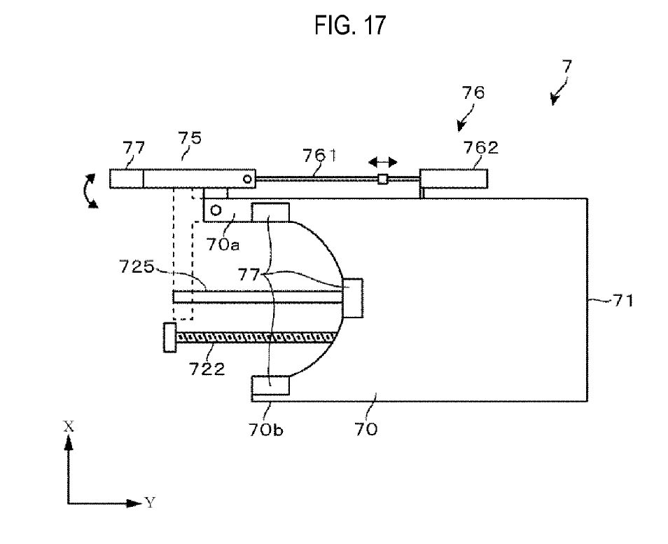

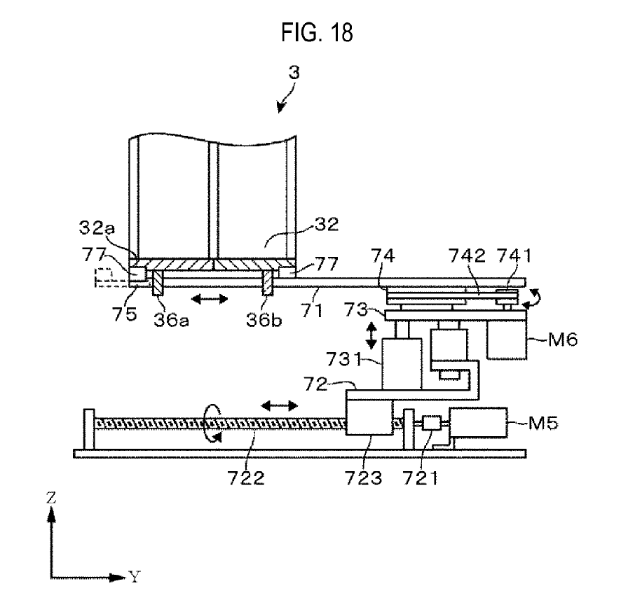

The boat conveyance instrument 7, as illustrated in FIGS. 17 and 18, includes a plate-shaped conveyance arm 71 on which the wafer boat 3 is mounted. The conveyance arm 71 is configured to advance or retreat by an advancing/retreating instrument, ascend or descend by an ascending/descending instrument, and rotate about a perpendicular axis by a rotation instrument. In the present example, the advancing/descending instrument is configured with a ball screw instrument, and by a motor M5 rotating a ball screw 722 through a coupling 721, a moving base 72 disposed at a top of the nut 723 moves along the ball screw 722. In FIG. 17, reference numeral 725 is a guide member.

Moreover, an ascending/descending base 73 is disposed through a cylinder 731 that constitutes an ascending/descending instrument, above the moving base 72. The conveyance arm 71 is horizontally disposed through a rotation base 74, above the ascending/descending base 73. The rotation base 74 rotates the conveyance arm 71 about a perpendicular axis by the combination of a pulley 741 and a belt 742 that are rotated by a motor M6. Therefore, the rotation instrument is configured with the motor M6, the pulley 741, the belt 742, and the rotation base 74.

In the present example, the boat conveyance instrument 7 is disposed such that when the first stage 51 and the second stage 52 are in the combining position, the conveyance arm 71 is disposed just inside the first and second stages 51 and 52. Furthermore, the conveyance arm 71 is disposed to advance or retreat along the lengthwise direction of the processing chamber 40, and as illustrated in FIGS. 11 and 18, the conveyance arm 71 is configured to advance to or retreat from a lower side of the bottom plate 32 of the wafer boat 3 that is in the combining position. In this case, when the conveyance arm 71 receives the wafer boat 3 that is in the combining position, the conveyance arm 71 advances to or retreats from a height position where the support leg 36a and the support leg 36b are disposed.

Moreover, a front end side of the conveyance arm 71 is configured in order for two arm parts 70a and 70b to extend from an arm body 70, and a movable arm 75 is disposed at a front end side of the arm part 70a. The movable arm 75 is configured to operate by a driving instrument 76, between a normal position (position that is illustrated as a solid line in FIG. 17) extending along the arm part 70a and a conveyance position (position that is illustrated as a dot line in FIG. 17) intersecting the arm part 70a. A driving instrument where a load 761 is combined with a cylinder 762, as illustrated in FIG. 17, is used as the driving instrument 76 as an example. In the driving instrument 76, when the cylinder 762 presses the load 761, the movable arm 75 is bent to intersect the arm part 70a and thus is in the conveyance position, and when the pressure is removed, the movable arm 75 returns to the normal position. Therefore, when the movable arm 75 is in the conveyance position, the support leg 36a and support leg 36b of the wafer boat 3 in the combining position are surrounded by the arm part 70a, the arm part 70b, and the movable arm 75.

In the boat conveyance instrument 7, the bottom plate 32 of the wafer boat 3 is disposed on the conveyance arm 71 and conveyed. However, in the conveyance arm 71, as illustrated in FIGS. 17 and 18, a boat receiving part 77 is disposed in a region where the bottom plate 32 is disposed. In the present example, the boat receiving part 77, for example, is disposed on the arm body 70, the two arm parts 70a and 70b, and the movable arm 75. In the bottom plate 32 of the wafer boat 3, a stepped portion 32a is formed in a region corresponding to the boat receiving part 77, and thus, a position is adjusted when the wafer boat 3 is disposed at the boat receiving part 77, whereby the deviation of the position of the wafer boat 3 can be prevented.

The boat elevator 8 and the insulation unit 81 will now be described in detail. The boat elevator 8, as illustrated in FIG. 11, constitutes a support instrument ascending/descending apparatus for loading or unloading the wafer boat 3 into or from the vertical heat treatment furnace 85, and is configured to ascend or descend by an ascending/descending instrument (not shown). Also, for example, the insulation unit 81 constitutes a heat insulating tube that is formed of quartz and, as illustrated in FIG. 19, is installed by disposing a cover 82 and a rotation table 83 at the boat elevator 8. On the top of the insulation unit 81, a disposing part 84 is disposed in a region where the support leg 36a and support leg 36b of the wafer boat 3 are disposed.

The wafer boat 3 that is in the combining position of the boat combining instrument 5 is conveyed to an upper side of the insulation unit 81, with the bottom plate 32 being supported by the conveyance arm 71. Subsequently, the wafer boat 3 disposes the support legs 36a and 36b at an upper side of the disposing part 84 corresponding thereto and, by descending, is transferred onto the disposing part 84. Therefore, the wafer boat 3 is disposed at the insulation unit 81, and then, by lifting the boat elevator 8, the wafer boat 3 is loaded into the vertical heat treatment furnace 85, whereupon a lower end side of the vertical heat treatment furnace 85 is closed by the cover 82.

The vertical heat treatment apparatus 4 is controlled by a control part 100. The control part 100, for example, is configured with a computer, and includes a program, a memory, and a Central Processing Unit (CPU). A command (each step), which allows the control part 100 to transfer a control signal to each part of the vertical heat treatment apparatus 4 and allows predetermined heat treatment to be performed, is written in the program. With the program being stored in a computer storage medium, for example, a storage part such as a flexible disk, a compact disk, a hard disk, Magneto Optical (MO) disk or the like, the program is installed in the control part 100.

Herein, the program includes a program for controlling the substrate moving mounting instrument 42, the boat combining instrument 5, the coupling instrument 6, the boat conveyance instrument 7, and the boat elevator 8. Accordingly, each part is controlled according to a process recipe that is previously stored in the memory of the control part 100.

The operation of the above-described vertical heat treatment apparatus 4 will be described in detail. First, the first stage 51 and second stage 52 of the boat combining instrument 5 become a moving mounting position, and the first boat part 1 and the second boat part 2 are respectively disposed at the first stage 51 and the second stage 52. Also, in the coupling instrument 6, the cap part 34 of the coupling member 33 is supported and moved to a coupling position of an upper side of a combining position.

The substrate moving mounting instrument 42 moves and mounts the wafer W, which is in the FOUP 41, onto the first boat part 1 and the second boat part 2. For example, the first rotation base 512 and the second rotation base 522 of the boat combining instrument 5 is in a combining direction, and the first moving base 511 and the second moving base 521 are moved to a combining position. Therefore, the first boat part 1 and the second boat part 2 are combined with each other, thereby configuring the wafer boat 3 with the wafer W mounted thereon.

Subsequently, by dropping the arm 61 of the coupling instrument 6, the foot part 35a of the coupling member 33 is inserted into the hole portion 12a of the ceiling part 31 of the wafer boat 3 and the foot part 35b of the coupling member 33 is inserted into the hole portion 22a of the ceiling part 31 of the wafer boat 3, whereby the first boat part 1 and the second boat part 2 are coupled to each other. The cap part 34 of the coupling member 33 is separated from a current position by opening the support instrument 66, and then the arm 61 ascends and moves to a standby position.

Subsequently, the boat conveyance instrument 7 conveys the wafer boat 3, which is in the combining position, to the insulation unit 81. First, when the movable arm 75 of the boat conveyance instrument 7 is in a normal position, the conveyance arm 71 advances to a position to which the wafer boat 3 is conveyed. Subsequently, the movable arm 75 moves to a conveying position, and then the conveyance arm 71 ascends, whereupon the boat receiving part 77 of the conveyance arm 71 receives the wafer boat 3 from the first stage 51 and the second stage 52. The wafer boat 3 is conveyed to an upper side of the insulation unit 81, and then by dropping the conveyance arm 71, the support leg 36a and the support leg 36b are disposed at the disposing part 84 of the insulation unit 81. Therefore, the wafer boat 3 is transferred to the insulation unit 81, and then the conveyance arm 71 retreats therefrom.

The boat elevator 8 ascends, the wafer boat 3 is loaded into the vertical heat treatment furnace 85, and heat treatment is performed on the wafers W mounted on the wafer boat 3 in batches. After the heat treatment ends, the boat elevator 8 descends, the wafer boat 3 is unloaded from the vertical heat treatment furnace 85, and the boat conveyance instrument 7 conveys the wafer boat 3 onto the first stage 51 and the second stage 52 that are in the combining position.

Subsequently, the coupling instrument 6 moves from the standby position to the coupling position, and then by opening and dropping the support instrument 66, the support instrument 66 is disposed near the cap part 34 of the coupling member 33. The cap part 34 is held by closing the support instrument 66, and then by lifting the arm part 61, the coupling member 33 is detached from the wafer boat 3.

Subsequently, the first stage 51 and the second stage 52 move to the moving mounting position. For example, when the first moving base 511 and the second moving base 521 are in the combining position, the wafer boat 3 is divided into the first boat part 1 and the second boat part 2 by opening the first rotation base 512 and the second rotation base 522 in the moving mounting direction, and the first moving base 511 and the second moving base 521 move to the moving mounting position. Also, when the first rotation base 512 and the second rotation base 522 are in the combining direction, the wafer boat 3 is divided into the first boat part 1 and the second boat part 2 by moving the first moving base 511 and the second moving base 521 to the moving mounting position, and the first rotation base 512 and the second rotation base 522 may move to the moving mounting direction. Subsequently, the substrate moving mounting instrument 42 moves and mounts the heat-treated wafers W, which are mounted on the first boat part 1 and the second boat part 2, to the FOUP 41.

According to the above-described embodiment, in respectively moving and mounting the wafers W1 and W2 onto the first and second boat parts 1 and 2, the wafers W1 and W2 are respectively move and mounted onto the first and second boat parts 1 and 2 for the first support part 16a to 16c and the second support part 26a to 26c that are disposed at arrangement intervals of A. Herein, for example, the arrangement interval of A is set to about 12 mm, and thus, a moving and mounting margin in an upward and downward direction is large, thereby enabling the easy moving and mounting operation of each of the wafers W1 and W2.

Moreover, the wafers W1 and W2 are respectively moved and mounted on the first and second boat parts 1 and 2, and then the first boat part 1 is combined with the second boat part 2, thereby constituting the wafer boat 3. Herein, in the wafer boat 3, the wafer W1 on the first boat part 1 and the wafer W2 on the second boat part 2 are alternately arranged in an upward and downward direction, and thus, the wafers W are arranged and supported at arrangement intervals of A/2 narrower than a case of moving and mounting wafers, on the wafer boat 3.

Accordingly, a moving and mounting operation can be easily performed for the wafer boat 3, and moreover, the arrangement interval between the wafers W on the wafer boat 3 can become narrower. Therefore, the number of mounted wafers can increase without changing the size of the wafer boat 3. As a result, the number of wafers W that are simultaneously heat-treated in the vertical heat treatment furnace 85 increases, thus increasing the number of wafers processed by the vertical heat treatment apparatus 4. Also, when the number of wafers W mounted on the wafer boat 3 is equal to the existing number of mounted wafers, the wafer boat 3 and the vertical heat treatment furnace 85 can be compact. Also, since the number of wafers W which are simultaneously heat-treated in the vertical heat treatment furnace 85 increases, the energy necessary to process one wafer W decreases, thus saving energy.

Moreover, since the first support part 16a to 16c and the second support part 26a to 26c are formed in a long arm shape, a wafer mounting region (a support surface) on which the wafer W is mounted is large. Herein, as described above, in a configuration where the wafers W are pushed out from the side support pillars 15a and 15c and support pillars 25a and 25c and mounted, when a support surface is small, stress due to the weight of a wafer W is concentrated on a portion that contacts the support surface in a back side of the wafer W, and thus, a contact portion of the back side of the wafer W can be easily damaged. The damage is known as one of the causes of a crystal defect (slip) that occurs in heat treatment. However, as described above, when respective support surfaces of the first support part 16a to 16c and the second support part 26a to 26c are enlarged, the stress can be dispersed. Accordingly, the back side of the wafer W is prevented from being damaged, and moreover, the crystal defect causing the damage can be prevented, thus enhancing production yield.

Moreover, since the first support part 16a to 16c and the second support part 26a to 26c are formed in a long arm shape and thus a support surface is large, the wafer W can be supported stably. Therefore, even when the wafers W1 and W2 are respectively moved and mounted on the first and second boat parts 1 and 2 and then the first and second boat parts 1 and 2 are moved for combining thereof, the wafer W can be prevented from being dropped. Particularly, since the side support parts 16a and 16c are disposed to extend outward across the linear region 14 and the side support parts 26a and 26c are disposed to extend outward across the linear region 24, even when the side support pillars 15a and 15c and support pillars 25a and 25c are disposed at the rear side of the wafer W instead of the center of the wafer W, the wafer W can be supported stably. Also, for the side support parts 16a and 16c and the side support parts 26a and 26c, the wafer W is transferred from the linear region 14 and the linear region 24, and thus, the linear region 14 side and the linear region 24 side are the front side of the wafer W and the central support pillar 15b side and the central support pillar 25b side are the rear side of the wafer W.

Moreover, since the wafer boat 3 of the present disclosure is configured by combining the first boat part 1 and the second boat part 2, the support pillars 15a to 15c of the first boat part 1 and the support pillars 25a to 25c of the second boat part 2 are arranged at certain intervals along the perimeter direction of a wafer W that is mounted on the wafer boat 3 after combination. In this case, as illustrated in FIG. 5, an interval between adjacent support pillars is set to be less than the diameter of the wafer W.

Therefore, even if a vibration is applied to the wafer boat 3 with the wafer W mounted thereon due to an earthquake or trouble during conveyance, the wafer W is prevented from protruding from the wafer boat 3 because the perimeter of the wafer W is surrounded by the support pillars 15a to 15c and 25a to 25c. Accordingly, even when a vibration is applied to the wafer boat 3, the wafer W is prevented from being dropped from the wafer boat 3, thus preventing damage to the wafer W.

Moreover, as described above, since the position of the outer border of the wafer W is regulated by the support pillars 15a to 15c and 25a to 25c, the side support parts 16a and 16c are disposed to extend outward across the linear region 14, and the side support parts 26a and 26c are disposed to extend outward across the linear region 24, even if a large vibration is applied to the wafer boat 3, the wafer W can be prevented from falling off each of the side support parts 16a, 16c, 26a and 26c. Accordingly, even when the wafer boat 3 vibrates, a wafer W is not dropped from a support part, thus preventing an accident such as a collision between different wafers W due to the drop.

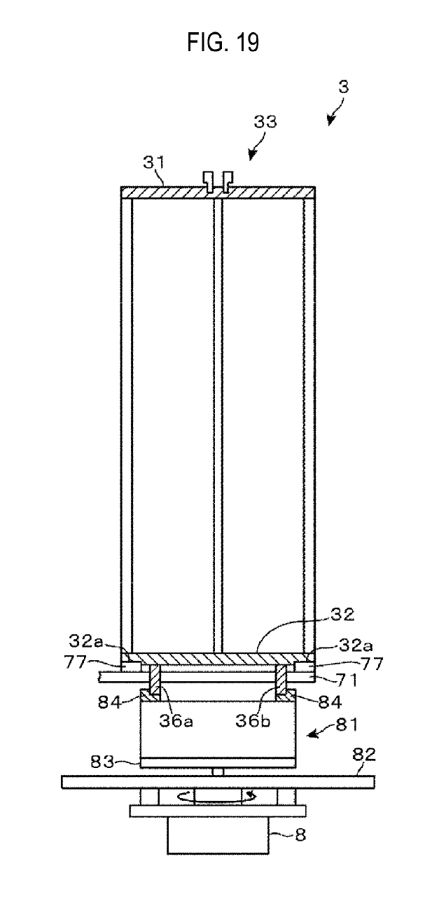

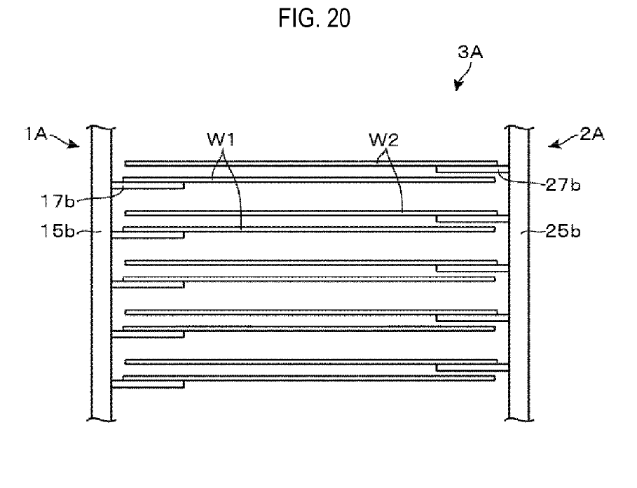

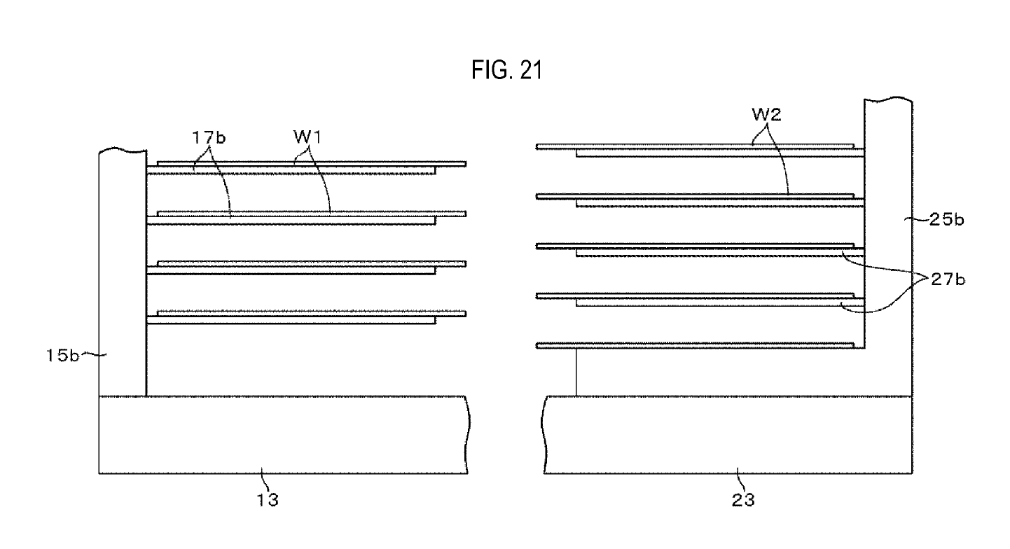

Another example of the wafer boat will now be described in detail with reference to FIGS. 20 to 23. In a wafer boat 3A of the present example, a wafer W is supported for a processed surface thereof to be downward oriented in one of a first boat part 1A and a second boat part 2A, and a wafer W is supported for a processed surface thereof to be upward oriented in the other boat part. In the present example, as illustrated in FIG. 20, a wafer W1 mounted on the first boat part 1A is disposed so that a back side thereof is oriented upward, and a wafer W2 mounted on the second boat part 2A is disposed so that a processed surface thereof is oriented upward.

Except that an arrangement interval between a plurality of support parts 17a to 17c disposed at the first boat part 1A differs from an arrangement interval between a plurality of support parts 27a to 27c disposed at the second boat part 2A, the first boat part 1A and the second boat part 2A are configured similarly to the first boat part 1 and second boat part 2 of the above-described wafer boat 3. Therefore, similar to the wafer boat 3, the wafer boat 3A is configured by combining the first boat part 1A and the second boat part 2A. In the wafer boat 3A, the wafer W1 mounted on the first boat part 1A and the wafer W2 mounted on the second boat part 2A are alternately arranged in an upward and downward direction.

Therefore, in the first boat part 1 and the second boat part 2, the wafers W1 and W2 adjacent in an upward and downward direction are disposed for processed surfaces thereof to face each other, and the wafers W1 and W2 are disposed so that back sides thereof face each other. In this case, the height position of each of the support parts 17a to 17c of the first boat part 1A and the height position of each of the support parts 27a to 27c of the second boat part 2A are set such that an interval between the processed surfaces of the wafers W facing each other is greater than an interval between the back sides of the wafers W facing each other, in a state where the first boat part 1 has been combined with the second boat part 2. Specifically, the support parts 17a to 17c of the first boat part 1A are disposed at arrangement intervals of about 12 mm, and the support parts 27a to 27c of the second boat part 2A are disposed at arrangement intervals of about 12 mm. Each of the height positions is set such that the interval between the processed surfaces of the wafers W facing each other is about 8 mm and the interval between the back sides of the wafers W facing each other is about 4 mm.

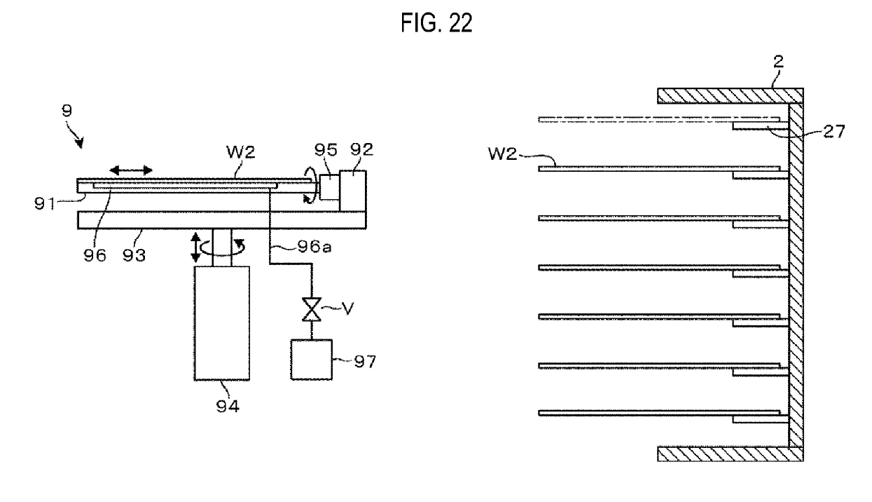

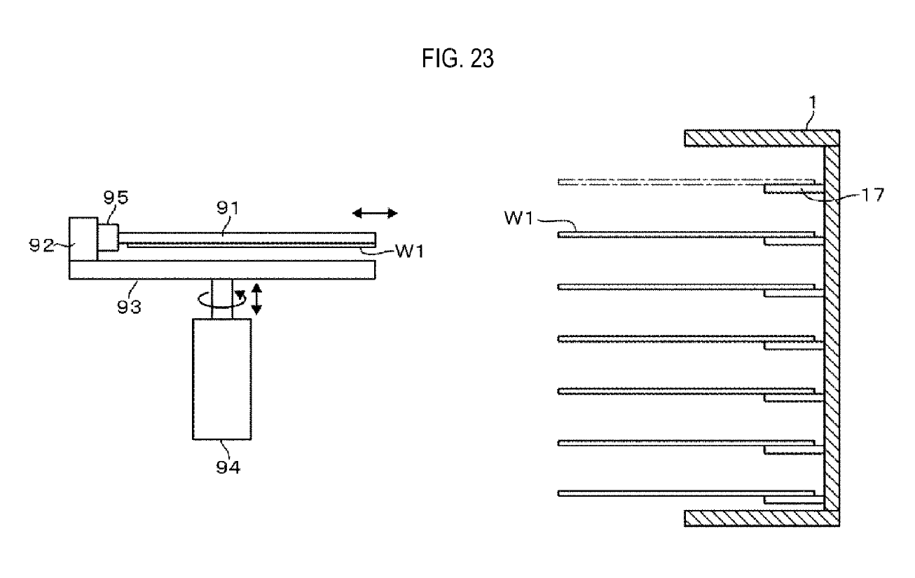

A vertical heat treatment apparatus including the first boat part 1A and the second boat part 2A is configured similarly to the vertical heat treatment apparatus 4 of FIG. 10, except that a substrate moving mounting apparatus 9 is configured as illustrated in FIGS. 22 and 23. The substrate moving mounting apparatus 9 is configured such that a horizontal fork 91 supporting the wafer W advances or retreats along a base crosspiece 93 by an advancing/retreating instrument 92 and the base crosspiece 93 ascends or descends and rotates about a perpendicular axis by the driving instrument 94.

Moreover, a base end side of the fork 91 is connected to a rotation instrument 95 that rotates about a horizontal axis. Also, an absorbing hole 96 that is connected to a vacuum pump 97 through an absorption path 96a is formed at the surface of the fork 91. Therefore, the wafer W is mounted on the fork 91, and then by opening a valve V1, the vacuum pump 97 performs an exhaust operation, whereby the wafer W is vacuum-absorption-supported on the fork 91 by the absorbing hole 96. Also, the wafer W may be absorption-supported on the fork 91 with an electrostatic force instead of vacuum absorption.

In the vertical heat treatment apparatus including the first boat part 1A and the second boat part 2A, as illustrated in FIG. 22, a wafer W2 is received from an FOUP 41 in order for a processed surface thereof to be upward oriented by the fork 91, and then transferred to the support parts 27 (27a to 27c) of the second boat part 2 in order for the processed surface to be upward oriented. Also, as illustrated in FIG. 23, a wafer W1 is received from the FOUP 41 in order for a processed surface thereof to be upward oriented by the fork 91, and then, for example, the wafer W1 advances such that the base end side of the fork 91 is disposed before a front end of the base crosspiece 93, whereupon the rotation instrument 95 rotates the fork 91 for the wafer W1 to be downward disposed. In this state, the back side of the wafer W1 is oriented upward, and the processed surface of the wafer W1 is oriented downward. The wafer W1 is transferred to the support part 17 (17a to 17c) of the first boat part 1 while the back side of the wafer W1 is oriented upward.

Accordingly, the wafer W1 and the wafer W2 are respectively moved and mounted on the first boat part 1A and the second boat part 2A, and then, as described above, the boat combining instrument 5 combines the boat parts 1A and 2A to constitute the wafer boat 3A. Subsequently, the wafer boat 3A is coupled to a coupling member 33, and then conveyed onto an insulation unit 81 by a boat conveyance instrument 7. A boat elevator 8 ascends, the wafer boat 3A is loaded into a vertical heat treatment furnace 85, and a predetermined heat treatment is performed on the wafers W1 and W2.

According to such a configuration, similar to the above-described embodiment, in moving and mounting the wafers W1 and W2, the wafers W1 and W2 are respectively transferred to the first and second boat parts 1A and 2A at a large arrangement interval, the wafer boat 3A is combined after moving and mounting the wafers W1 and W2. Therefore, a moving and mounting operation becomes easier by increasing a moving and mounting margin, and an arrangement interval between the wafers W1 and W2 mounted on the wafer boat 3 can become narrower. Accordingly, the number of wafers W1 and W2 mounted on the wafer boat 3 increases, thus enhancing the number of processed wafers.

Moreover, the wafer W1 of which the back side is upward oriented is moved and mounted on the first boat part 1A, the wafer W2 of which the processed surface is upward oriented is moved and mounted on the second boat part 2A, and then the wafer boat 3 is configured. Therefore, even when the wafers W1 and W2 adjacent in an upward and downward direction are arranged such that the processed surfaces face each other and the back sides face each other, the moving and mounting operation can be easily performed. In the wafers W1 and W2 adjacent in an upward and downward direction, moreover, a region where the processed surfaces face each other is set to have an interval greater than that of a region where the back sides face each other. Accordingly, processing gas is easily injected into a region where the processed surfaces of the wafers W1 and W2 face each other, and thus, the processing gas is widely and sufficiently spread into the processed surfaces of the wafers W1 and W2, whereby the occurrence of processing non-uniformity is prevented and heat treatment having high in-surface uniformity can be performed.

In the present disclosure, the wafer W1 mounted on the first boat part is not assumed as being completely (100%) overlapped with the wafer W2 mounted on the second boat part. When the wafer W1 is not completely overlapped with the wafer W2, a configuration is not necessarily required where the wafers W1 and W2 are supported by extending a support part from a support pillar. For example, grooves that are arranged along the support pillar and horizontally cut constitute the support part.

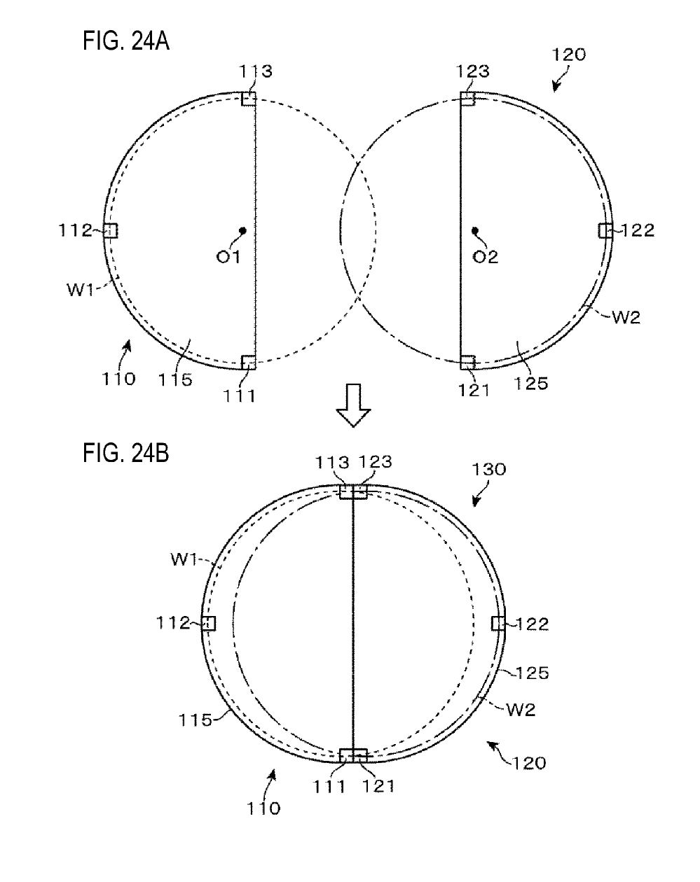

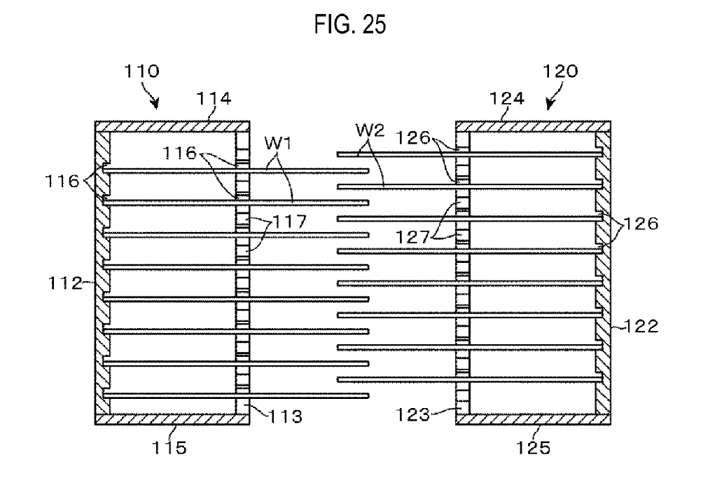

Such a configuration will now be described in detail with reference to FIGS. 24A to 26. In the drawings, reference numeral 110 indicates a first boat part, and reference numeral 120 indicates a second boat part. A plurality of support pillars, for example, three support pillars 111 to 113 are disposed at the first boat part 110, and a plurality of support pillars, for example, three support pillars 121 to 123 are disposed at the second boat part 120. In the first boat part 110, when a side where the central support pillar 112 is disposed is one end side, the support pillars 111 and 113 of both sides are disposed at the other end side instead of a center 01 of the wafer W1. Also, likewise, the support pillars 121 and 123 of both sides in the second boat part 120 are disposed at one end side instead of a center 02 of the wafer W2. In FIGS. 24A and 24B, and FIG. 25, reference numeral 114 is a ceiling plate of the first boat part 110, reference numeral 124 is a ceiling plate of the second boat part 120, reference numeral 115 indicates a bottom plate of the first boat part 110, and reference numeral 125 indicates a bottom plate of the second boat part 120.

In the support pillars 111 to 113, groove portions 116 where a peripheral edge portion of the wafer W1 is disposed are horizontally cut and thus formed. In the support pillars 121 to 123, groove portions 126 where a peripheral edge portion of the wafer W2 is disposed are horizontally cut and thus formed. In this case, the groove portion 116 and the groove portion 126 are arranged and formed one over the other such that the wafer W1 mounted on the first boat part 110 and the wafer W2 mounted on the second boat part 120 are alternately arranged in an upward and downward direction. As described above, the support pillars 111 and 113 of both sides are formed more outward than the center 01 of the wafer W1, and the support pillars 121 and 123 of both sides are formed more outward than the center 02 of the wafer W2, whereby the peripheral edge of the wafer W is disposed in each of the groove portions 116 and the groove portions 126, and thus, the wafers W1 and W2 are horizontally supported in the first and second boat parts 110 and 120, respectively.

Moreover, in both side support pillars 111 and 113 of the first boat part 110, the groove portion 117 is cut and formed such that it does not cause interference with the wafer W2 mounted on the second boat part 2. Likewise, in both side support pillars 121 and 123 of the second boat part 120, the groove portion 127 is cut and formed such that it does not cause interference with the wafer W1 mounted on the first boat part 1.

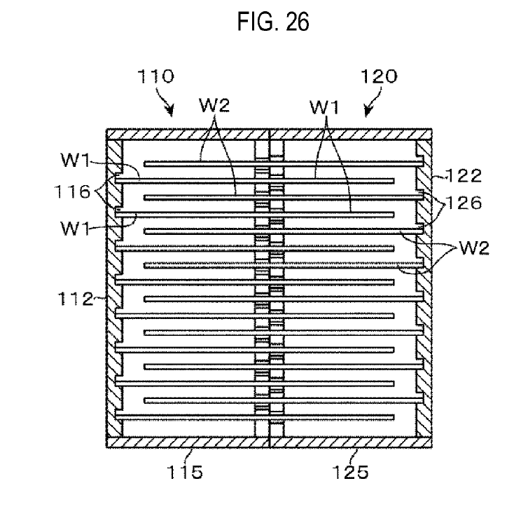

Therefore, the wafers W1 and W2 are respectively mounted on the first and second boat parts 110 and 120, and then by combining the first boat part 110 and the second boat part 120, as illustrated in FIGS. 24A and 24B, and FIG. 26, the wafer boat 130 is configured. In this case, as illustrated in the drawings, although the wafers W1 and W2 are not completely overlapped with each other on the wafer boat 130, by loading the wafer boat 130 into the vertical heat treatment furnace, heat treatment may be performed on the wafers W1 and W2 in batches.

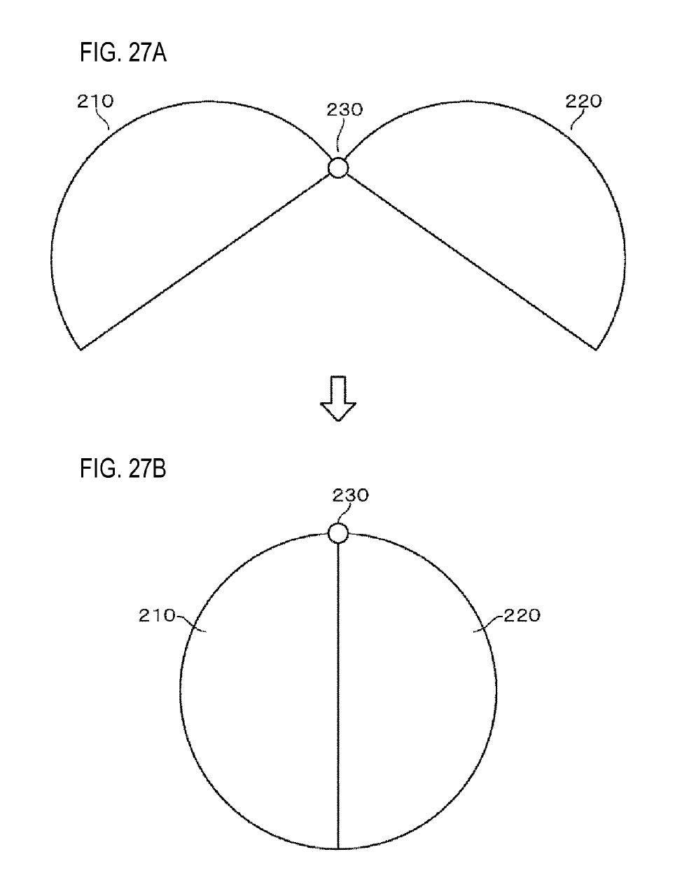

In the above description, the wafer boat is not limited to being completely divided into the first boat part and the second boat part, and as illustrated in FIGS. 27A and 27B, the spirit and scope of the present disclosure also include a configuration where the first boat part 210 and the second boat part 220 are opened while the first boat part 210 is partially connected to the second boat part 220, in moving and mounting the wafer W. In this case, for example, a common support pillar 230 is installed, and the ceiling plate and bottom plate of each of the first and second boat parts 210 and 220 are joined to and detached from the support pillar 230 by using a hinge instrument (not shown).

Moreover, in the present disclosure, a support part formed at a support pillar is not limited to the above description, and may be disposed to extend outward across a ceiling plate (bottom plate) from a central support pillar. Also, a support part that extends near a ceiling plate (bottom plate) may be disposed at a side support pillar. Moreover, a support part formed at a support pillar may be formed by combining an arm portion (which extends from the support pillar) and a groove portion that is cut at the support pillar.

Moreover, in the present disclosure, one of a first disposing part (first stage) and a second disposing part (second stage) is fixed, and the other is moved, whereby a first support instrument portion (first boat part) on the first disposing part may be combined with a second support instrument portion (second boat part) on the second disposing part. Also, a support instrument moving mounting apparatus may convey the first support instrument portion and the second support instrument portion onto a support instrument ascending/descending apparatus, and allow the first support instrument portion and the second support instrument portion to be combined with each other on the support instrument ascending/descending apparatus.

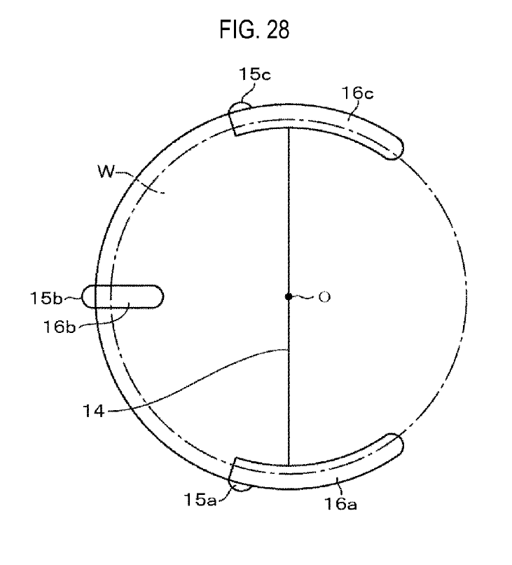

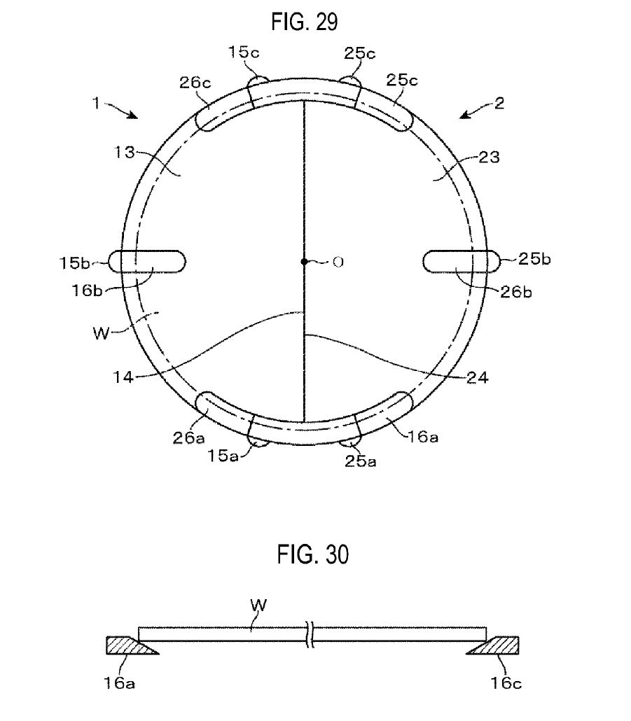

Moreover, in the present disclosure, the side support part 16a (26a) and the side support part 16c (26c) that respectively support the sides of a wafer W may be disposed to extend more toward a front side than the center of the wafer W supported by the support parts 16a to 16c (26a to 26c), and as illustrated in FIG. 28 with the side support parts 16a and 16c as an example, a support surface of each of the side support parts 16a and 16c may be formed in a circular arc shape along a peripheral edge of the wafer W. FIG. 29 illustrates a state where the first boat part 1 is joined to the second boat part 2. Also, although the central support part 16b and the central support part 26b are configured similarly to the above-described example of FIG. 5, the central support part 16b may be formed in a circular arc shape along a peripheral edge of a wafer W, and the central support part 26b may be formed in a circular arc shape along a peripheral edge of a wafer W.

In such a configuration, since the side support part 16a (26a) and the side support part 16c (26c) are disposed along the peripheral edge of the wafer W, a long support surface along a perimeter direction is formed at the side of the wafer W. Therefore, the wafer W is pushed out from the side support pillar 15a (25a) and the side support pillar 15c (25c) and disposed of, and in the peripheral edge portion of the side of the wafer W on which a stress due to the weight of the wafer W is frequently concentrated, the stress can be dispersed. Accordingly, a back side of a wafer can be prevented from being damaged, and a crystal defect causing damage can be prevented, thus enhancing production yield.

Moreover, when seen from a member that transfers the wafer W to the first boat part 1 and the second boat part 2, a plurality of support parts respectively disposed at both sides of the wafer W, for example, the side support part 16a (26a) and the side support part 16c (26c) may be disposed such that the support surface of the wafer W is downward inclined toward the central axis of the wafer W. In such a configuration, the lower periphery of the wafer W is supported by the support surface of each of the side support part 16a (26a) and the side support part 16c (26c), with the wafer positioned in an inclined surface. In this case, the height position of the support surface of the central support part 16b is set in correspondence with the height position of the wafer W that is supported by the side support part 16a and the side support part 16c, and the height position of the support surface of the central support part 26b is set in correspondence with the height position of the wafer W that is supported by the side support part 26a and the side support part 26c. Herein, a region contacting the support surface in the lower periphery of the wafer W secures a certain length, and thus, the stress is dispersed, thereby preventing the occurrence of the crystal defect. Also, the lower periphery of the wafer W contacts the support surface, and thus, even if a crystal defect occurs in a contact region, the quality of a product can be prevented from being badly affected by the crystal defect because the contact region is disposed outside a pattern forming region.

Moreover, as described above, since the position of the wafer W has been determined previously, the moving of the wafer W to a side is suppressed. Therefore, even when moving the first boat part 1 and the second boat part 2, the wafer W is stably supported, thus preventing the wafer W from being dropped. Herein, the support surface of each of the central support parts 16a and 26a may also be formed to be inclined downward. Moreover, for example, as illustrated in FIGS. 24A to 26, even in the support part configured with the grooves that are arranged along the support pillar and horizontally cut, the support surface may be formed to be downward inclined toward the central axis of the wafer W.

According to the present disclosure, the substrate support instrument is configured with the first support instrument part and the second support instrument part which are detachably combined with each other, and the support parts are respectively disposed at the first and second support instrument parts such that substrates respectively supported by the first and second support instrument parts are alternately arranged when the first and second support instrument parts are coupled to each other. Therefore, when respective substrates are moved and mounted on the first support instrument part and the second support instrument part and then the substrate support instrument is configured by combining the first and second support instrument parts, the arrangement pitch of substrates mounted on the substrate support instrument becomes narrower than that of substrates which are respectively moved and mounted on the first and second support instrument parts. Accordingly, the moving and mounting margin can be secured, and moreover, the arrangement pitch of substrates mounted on the substrate support instrument can become narrower.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate support instrument which supports a plurality of substrates in a shelf shape and loads the substrates into a vertical heat treatment furnace for performing heat treatment, the substrate support instrument comprising:
a first support instrument portion and a second support instrument portion detachably combined with each other, each of the first support instrument portion and second support instrument portion comprising:
a ceiling plate and a bottom plate facing each other upward and downward;
a support pillar disposed in plurality along a peripheral edge portion of each of the ceiling plate and bottom plate, and configured to connect the ceiling plate and the bottom plate; and
a support part disposed at a position corresponding to each of the support pillars, and configured to support a bottom of each of the substrates,
wherein in the support part of each of the first support instrument portion and the second support instrument portion, a height position is set such that a substrate supported in the first support instrument portion and a substrate supported in the second support instrument portion are alternately arranged, when the first support instrument portion is combined with the second support instrument portion.

2. The substrate support instrument of claim 1, wherein the support part of each of the first support instrument portion and second support instrument portion is configured with an arm portion for support which extends from the support pillar.

3. The substrate support instrument of claim 1, further comprising a coupling member disposed to be detachable from the first support instrument portion and the second support instrument portion so as to couple the combined first support instrument portion and second support instrument portion.

4. The substrate support instrument of claim 2, wherein,
each of the substrates is a circular substrate, and
at least one of the support parts is configured such that a support surface with the substrate disposed thereon is formed in a circular arc shape along a peripheral edge of the substrate.

5. The substrate support instrument of claim 1, wherein when seen from a member which transfers a substrate to each of the first support instrument portion and second support instrument portion, a plurality of support parts respectively disposed at both sides of the substrate are disposed such that a support surface of the substrate is inclined downward toward a central axis of the substrate and a lower periphery of the substrate is supported by the support surface.

6. A vertical heat treatment apparatus which supports a plurality of substrates on a substrate support instrument having a shelf shape and loads the substrates into a vertical heat treatment furnace, the vertical heat treatment apparatus comprising:
a first disposing part installed for disposing a first support instrument portion at a position where a substrate is transferred to the first support instrument portion, and using the substrate support instrument of claim 1 as the substrate support instrument;
a second disposing part installed for disposing a second support instrument portion at a position where a substrate is transferred to the second support instrument portion;
a combined instrument configured to combine the first support instrument portion disposed at the first disposing part and the second support instrument portion disposed at the second disposing part; and
a support instrument ascending/descending apparatus configured to load or unload the substrate support instrument into or from the vertical heat treatment apparatus, the substrate support instrument being configured by the combining instrument for combining the first support instrument portion and the second support instrument portion.

7. The vertical heat treatment apparatus of claim 6, wherein the combining instrument is a moving instrument which moves at least one of the first disposing part and second disposing part from a position where transfer of a substrate is performed.

8. The vertical heat treatment apparatus of claim 6, further comprising a support instrument moving mounting apparatus configured to move and mount the substrate support instrument with the first and second support instrument portions combined therein onto the support instrument ascending/descending apparatus.

9. The vertical heat treatment apparatus of claim 6, wherein,
in one of the first support instrument portion and second support instrument portion, a substrate is supported for a processed surface thereof to be oriented downward,
in the other, a substrate is supported for a processed surface thereof to be oriented upward, and
when the first support instrument portion has been combined with the second support instrument portion, a height position of a support part of each of the first and second support instrument portions is set such that an interval between processed surfaces of substrates facing each other becomes greater than an interval between back sides of the substrates facing each other.

10. A method of driving a vertical heat treatment apparatus which supports a plurality of substrates on a substrate support instrument having a shelf shape and loads the substrates into a vertical heat treatment furnace to perform heat treatment on the substrates, the method comprising:
supporting a substrate having a shelf shape on a first support instrument portion which is disposed at a first disposing part, by using the substrate support instrument of claim 1 as the substrate support instrument;
supporting a substrate having a shelf shape on a second support instrument portion which is disposed at a second disposing part;
combining the first support instrument portion and the second support instrument portion to constitute a substrate support instrument; and
loading the substrate support instrument into the vertical heat treatment furnace to perform heat treatment on a substrate.

11. The method of claim 10, further comprising:
supporting a substrate for a processed surface thereof to be oriented downward, for one of the first support instrument portion and second support instrument portion; and
supporting a substrate for a processed surface thereof to be oriented upward, for the other,
wherein when the first support instrument portion has been combined with the second support instrument portion, a height position of a support part of each of the first and second support instrument portions is set such that an interval between processed surfaces of substrates facing each other becomes greater than an interval between back sides of the substrates facing each other.
